(19) United States
(12) Patent Application Publication
(10) Pub. No.: US 2012/0325524 A1
(43) Pub. Date: Dec. 27, 2012

(54) FLEX-RIGID WIRING BOARD AND METHOD FOR MANUFACTURING THE SAME

(75) Inventors: Nobuyuki NAGANUMA, Ogaki-shi (JP); Hidetoshi Noguchi, Ogaki-shi (JP)

(73) Assignee: IBIDEN CO., LTD., Ogaki-shi (JP)

(21) Appl. No.: 13/482,299

(22) Filed: May 29, 2012

Related U.S. Application Data
(60) Provisional application No. 61/500,361, filed on Jun. 23, 2011.

(51) Int. Cl. H05K 1/11; H05K 3/36

(52) U.S. Cl. 174/254; 29/830

(57) ABSTRACT

A flex-rigid wiring board has a first rigid wiring board having a first inner layer and a first terminal on the first inner layer, a second rigid wiring board having a second inner layer and a second terminal on the second inner layer, and a flexible wiring board connecting the boards and having third and fourth terminals on the flexible board. The first and second boards have openings and are positioned such that the boards are spaced apart and form a recess portion formed of the openings facing each other, the flexible board is in the recessed portion such that the first terminal is connected to the third terminal and the second terminal is connected to the fourth terminal, and the first board has an interlayer conductor through an insulation layer in the first board such that the conductor is not directly under the first terminal.

### CROSS-REFERENCE TO RELATED APPLICATIONS

The present application is based on and claims the benefit of priority to U.S. Application No. 61/500,361, filed Jun. 23, 2011, the entire contents of which are incorporated herein by reference.

### BACKGROUND OF THE INVENTION

1. Field of the Invention

The present invention relates to a flex-rigid wiring board and its manufacturing method.

2. Discussion of the Background

Japanese Laid-Open Patent Publication No. 2006-140213 describes a flex-rigid wiring board where a flexible wiring board is positioned in a side direction of a core substrate, and two rigid wiring boards are connected through the flexible wiring board. Japanese Laid-Open Patent Publication No. 2005-322871 describes a flex-rigid wiring board where a flexible wiring board is mounted on a surface of each of two rigid wiring boards so that the two rigid wiring boards are connected through the flexible wiring board. The contents of Japanese Laid-Open Patent Publication Nos. 2006-140213 and 2005-322871 are incorporated herein by reference in the present application.

### SUMMARY OF THE INVENTION

According to one aspect of the present invention, a flex-rigid wiring board has a first rigid wiring board having insulation layers including a first inner insulation layer, the first rigid wiring board having a first connection terminal formed on a surface of the first inner insulation layer, a second rigid wiring board having insulation layers including a second inner insulation layer, the second rigid wiring board having a second connection terminal formed on a surface of the second inner insulation layer, and a flexible wiring board connecting the first rigid wiring board and the second rigid wiring board and having a third connection terminal formed on a surface of the flexible wiring board and a fourth connection terminal on the surface of the flexible wiring board. The first rigid wiring board and the second rigid wiring board have a first opening portion and a second opening portion, respectively, and are positioned such that the first rigid wiring board and the second rigid wiring board are spaced apart and form a recess portion including the first opening portion and the second opening portion facing each other, the flexible wiring board is positioned in the recessed portion such that the first connection terminal in the first rigid wiring board is connected to the third connection terminal in the flexible wiring board and that the second connection terminal in the second rigid wiring board is connected to the fourth connection terminal in the flexible wiring board, and the first rigid wiring board has a first interlayer connection conductor formed through one of the insulation layers in the first rigid wiring board such that the first interlayer connection conductor is not directly under the first connection terminal.

According to another aspect of the present invention, a method for manufacturing a flex-rigid wiring board includes preparing a first rigid wiring board having insulation layers including a first inner insulation layer, the first rigid wiring board having a first connection terminal formed on a surface of the first inner insulation layer, preparing a second rigid wiring board having insulation layers including a second inner insulation layer, the second rigid wiring board having a second connection terminal formed on a surface of the second inner insulation layer, preparing a flexible wiring board having a third connection terminal formed on a surface of the flexible wiring board and a fourth connection terminal on the surface of the flexible wiring board, positioning the first rigid wiring board and the second rigid wiring board spaced apart, and connecting the flexible wiring board to the first rigid wiring board and the second rigid wiring board such that the first connection terminal in the first rigid wiring board is connected to the third connection terminal in the flexible wiring board and that the second connection terminal in the second rigid wiring board is connected to the fourth connection terminal in the flexible wiring board. The first rigid wiring board and the second rigid wiring board have a first opening portion and a second opening portion, respectively, and are positioned such that the first rigid wiring board and the second rigid wiring board form a recess portion including the first opening portion and the second opening portion facing each other, the flexible wiring board is positioned in the recessed portion, and the first rigid wiring board has a first interlayer connection conductor formed through one of the insulation layers in the first rigid wiring board such that the first interlayer connection conductor is not directly under the first connection terminal.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a flex-rigid wiring board according to a first embodiment of the present invention;

FIG. 2 is a cross-sectional view showing a flexible wiring board of the flex-rigid wiring board according to the first embodiment of the present invention;

FIG. 3A is a cross-sectional view showing a first rigid wiring board of the flex-rigid wiring board according to the first embodiment of the present invention in a state where the flexible wiring board is mounted thereon;

FIG. 3B is a cross-sectional view showing a second rigid wiring board of the flex-rigid wiring board according to the first embodiment of the present invention in a state where the flexible wiring board is mounted thereon;

FIG. 4A is a plan view of the first rigid wiring board shown in FIG. 3A in a state where the flexible wiring board is not mounted thereon;

FIG. 4B is a plan view of the second rigid wiring board shown in FIG. 3B in a state where the flexible wiring board is not mounted thereon;

FIG. 5 is a plan view of the flexible wiring board shown in FIG. 2;

FIG. 6 is a plan view of the flex-rigid wiring board shown in FIG. 1;

FIG. 7A is a cross-sectional view showing a first bonding material for connecting a connection terminal of a rigid wiring board and a connection terminal of the flexible wiring board in the flex-rigid wiring board according to the first embodiment of the present invention;

FIG. 7B is a cross-sectional view showing a second bonding material for connecting a connection terminal of a rigid wiring board and a connection terminal of the flexible wiring board in the flex-rigid wiring board according to the first embodiment of the present invention;

FIG. 7C is a cross-sectional view showing a third bonding material for connecting a connection terminal of a rigid wiring board and a connection terminal of the flexible wiring board in the flex-rigid wiring board according to the first embodiment of the present invention;

FIG. 8A is, in a method for manufacturing a flex-rigid wiring board according to the first embodiment of the present invention, a view to illustrate a first step for preparing a first rigid wiring board;

FIG. 8B is a view to illustrate a second step subsequent to the step in FIG. 8A;

FIG. 9A in the method for manufacturing a flex-rigid wiring board according to the first embodiment of the present invention, a view to illustrate a first step for preparing a second rigid wiring board;

FIG. 9B is a view to illustrate a second step subsequent to the step in FIG. 9A;

FIG. 10A is, in the method for manufacturing a flex-rigid wiring board according to the first embodiment of the present invention, a view showing a panel (an assembly of wiring boards) where multiple first rigid wiring boards are formed in an integrated fashion;

FIG. 10B is, in the method for manufacturing a flex-rigid wiring board according to the first embodiment of the present invention, a view showing a panel (an assembly of wiring boards) where multiple second rigid wiring boards are formed in an integrated fashion;

FIG. 10C is, in the method for manufacturing a flex-rigid wiring board according to the first embodiment of the present invention, a view showing a panel (an assembly of wiring boards) where multiple flexible wiring boards are formed in an integrated fashion;

FIG. 11 is, in the method for manufacturing a flex-rigid wiring board according to the first embodiment of the present invention, a view showing a first rigid wiring board, second rigid wiring board and flexible wiring board which are individually set;

FIG. 12 is, in the method for manufacturing a flex-rigid wiring board according to the first embodiment of the present invention, a view to illustrate a step for preparing a frame;

FIG. 13A is, in the method for manufacturing a flex-rigid wiring board according to the first embodiment of the present invention, a view showing a first example of a method for connecting rigid wiring boards and a frame;

FIG. 13B is, in the method for manufacturing a flex-rigid wiring board according to the first embodiment of the present invention, a view showing a second example of a method for connecting rigid wiring boards and a frame;

FIG. 14 is, in the method for manufacturing a flex-rigid wiring board according to the first embodiment of the present invention, a view to illustrate a step for mounting a flexible wiring board on rigid wiring boards;

FIG. 15A is, in the method for manufacturing a flex-rigid wiring board according to the first embodiment of the present invention, a view to illustrate a first step for mounting a flexible wiring board on rigid wiring boards using the first bonding material shown in FIG. 7A;

FIG. 15B is a view to illustrate a second step subsequent to the step in FIG. 15A;

FIG. 15C is a view to illustrate a third step subsequent to the step in FIG. 15B;

FIG. 16A is, in the method for manufacturing a flex-rigid wiring board according to the first embodiment of the present invention, a view to illustrate a first step for mounting a flexible wiring board on rigid wiring boards using the second or third bonding material shown in FIG. 7B or 7C;

FIG. 16B is a view to illustrate a second step subsequent to the step in FIG. 16A;

FIG. 16C is a view to illustrate a third step subsequent to the step in FIG. 16B;

FIG. 17 is a view showing a state where a flex-rigid wiring board according to the first embodiment of the present invention is connected to a frame;

FIG. 18 is a cross-sectional view of a flex-rigid wiring board according to a second embodiment of the present invention;

FIG. 19A is a plan view of a first rigid wiring board of the flex-rigid wiring board shown in FIG. 18 in a state without a flexible wiring board mounted thereon;

FIG. 19B is a plan view of a second rigid wiring board of the flex-rigid wiring board shown in FIG. 18 in a state without a flexible wiring board mounted thereon;

FIG. 20 is a cross-sectional view of a flex-rigid wiring board according to another embodiment of the present invention;

FIG. 21 is a cross-sectional view showing another example in which a stacked-conductor structure is positioned directly under a connection terminal for mounting a flexible wiring board in a rigid wiring board of the flex-rigid wiring board according to the first embodiment of the present invention;

FIG. 22 is a cross-sectional view showing another example in which a stacked-conductor structure is positioned directly under a connection terminal for mounting a flexible wiring board in a rigid wiring board of the flex-rigid wiring board according to the second embodiment of the present invention;

FIG. 23 is a cross-sectional view showing a flex-rigid wiring board where a rigid wiring board according to the first embodiment is combined with a rigid wiring board according to the second embodiment;

FIG. 24 is, in yet another embodiment of the present invention, a cross-sectional view showing a flex-rigid wiring board where the number of conductive layers is different in a first rigid wiring board and a second rigid wiring board;

FIG. 25 is, in yet another embodiment of the present invention, a plan view showing a flex-rigid wiring board which is connected to a frame along with other wiring boards;

FIG. 26A is a plan view showing a first shape of conductive patterns in yet another embodiment of the present invention;

FIG. 26B is a plan view showing a second shape of conductive patterns in yet another embodiment of the present invention;

FIG. 26C is a plan view showing a third shape of conductive patterns in yet another embodiment of the present invention;

FIG. 26D is a plan view showing a fourth shape of conductive patterns in yet another embodiment of the present invention;

FIG. 26E is a plan view showing a fifth shape of conductive patterns in yet another embodiment of the present invention;

FIG. 27 is a plan view showing a first alternative example of a recessed portion for positioning the flexible wiring board of a flex-rigid wiring board in embodiments of the present invention;

FIG. 28 is a plan view showing a second alternative example of a recessed portion for positioning the flexible wiring board of a flex-rigid wiring board in embodiments of the present invention;

FIG. 29 is, in yet another embodiment of the present invention, a cross-sectional view of a flex-rigid wiring board where wall surfaces of opening portions (which eventually become a recessed portion formed by such opening portions) formed in rigid wiring boards are tapered;

FIG. 30 is, in yet another embodiment of the present invention, a cross-sectional view showing a flex-rigid wiring board where three or more steps are formed by opening portions in rigid wiring boards;

FIG. 31 is, in yet another embodiment of the present invention, a cross-sectional view showing a flex-rigid wiring board where the flexible wiring board is positioned on the middle step of the steps formed by opening portions;

FIG. 32 is, in yet another embodiment of the present invention, a cross-sectional view showing a flex-rigid wiring board which is formed with rigid wiring boards having no stacked-conductor structure;

FIG. 33A is, in yet another embodiment of the present invention, a view showing a panel (an assembly of wiring boards) where multiple first rigid wiring boards are formed in an integrated fashion;

FIG. 33B is, in yet another embodiment of the present invention, a view showing a panel (an assembly of wiring boards) where multiple flexible wiring boards are formed in an integrated fashion;

FIG. 33C is, in yet another embodiment of the present invention, a view showing a panel (an assembly of wiring boards) where multiple frame units (including second rigid wiring boards) are formed in an integrated fashion;

FIG. 34 is a view showing a first rigid wiring board, a flexible wiring board, and a frame unit (that includes second rigid wiring boards) which are individually set; and

FIG. 35 is a view showing yet another embodiment of the present invention where flex-rigid wiring boards are connected to a frame.

### DETAILED DESCRIPTION OF THE EMBODIMENTS

The embodiments will now be described with reference to the accompanying drawings, wherein like reference numerals designate corresponding or identical elements throughout the various drawings.

In the drawings, arrows (Z1, Z2) each indicate a lamination direction in a wiring board corresponding to a direction along a normal line (or a thickness direction of the wiring board) to the main surfaces (upper and lower surfaces) of the wiring board. On the other hand, arrows (X1, X2) and (Y1, Y2) each indicate a direction perpendicular to a lamination direction (or a direction to a side of each layer). The main surfaces of the wiring board are on the X-Y plane. Side surfaces of the wiring board are on the X-Z plane or the Y-Z plane. “Directly on” or “directly under” means direction Z (Z1 side or Z2 side).

In the present embodiment, the side closer to a core (substrate 200) is referred to as a lower layer, and the side farther from the core as an upper layer in a lamination direction.

A conductive layer is formed with one or multiple conductive patterns. A conductive layer may include a conductive pattern that forms an electrical circuit such as wiring (including ground), a pad, a land or the like, for example, or it may include a planar conductive pattern that does not form an electrical circuit.

Opening portions include notches and cuts other than holes and grooves. Holes are not limited to penetrating holes, and non-penetrating holes are also referred to as holes.

Among the conductors formed in opening portions, conductive film formed on inner surfaces of an opening portion (wall or bottom surface) is referred to as a conformal conductor, and conductor filled in an opening portion is referred to as a filled conductor. Also, conductor formed in a via hole (wall or bottom surface) is referred to as a via conductor, and conductor formed in a through hole (wall surface) as a through-hole conductor. A stacked-conductor structure means an assembly formed by stacking filled conductors in two or more layers.

Plating includes wet plating such as electrolytic plating as well as dry plating such as PVD (physical vapor deposition) and CVD (chemical vapor deposition).

Interlayer connection means electrically connecting the conductors on different layers to each other.

### First Embodiment

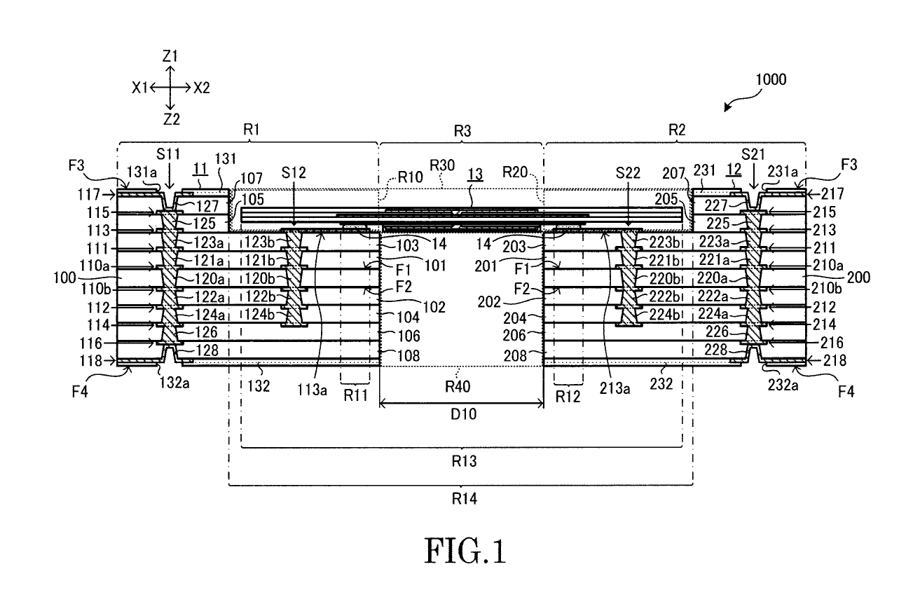

Flex-rigid wiring board 1000 of the present embodiment is a printed wiring board. Flex-rigid wiring board 1000 has rigid wiring boards (11, 12) and flexible wiring board 13 as shown in FIG. 1. Rigid wiring board 11 with substrate 100 as its core substrate and rigid wiring board 12 with substrate 200 as its core substrate are connected to each other by flexible wiring board 13. In the following, one (Z1 side) of upper and lower surfaces (two main surfaces) of substrate 100 or 200 is referred to as first surface (F1) and the other (Z2 side) as second surface (F2). In addition, one (Z1 side) of upper and lower surfaces (two main surfaces) of rigid wiring board 11 or 12 is referred to as third surface (F3) and the other (Z2 side) as fourth surface (F4).

Rigid wiring board 11 (first rigid wiring board) has opening portion (R10) (first opening portion) that reaches inner insulation layer 103 (first insulation layer), and rigid wiring board 12 (second rigid wiring board) has opening portion (R20) (second opening portion) that reaches inner insulation layer 203 (second insulation layer). Then, when rigid wiring board 11 and rigid wiring board 12 are positioned at distance (D10) in direction X in such a way that opening portion (R10) faces opening portion (R20), recessed portion (R30) and recessed portion (R40) connected to recessed portion (R30) are formed. Distance (D10) is set at 50 mm, for example.

In FIG. 1, flexible section (R3) is a flexible section sandwiched by rigid section (R1) and rigid section (R2), namely, part of flexible wiring board 13 exposed between rigid wiring board 11 and rigid wiring board 12.

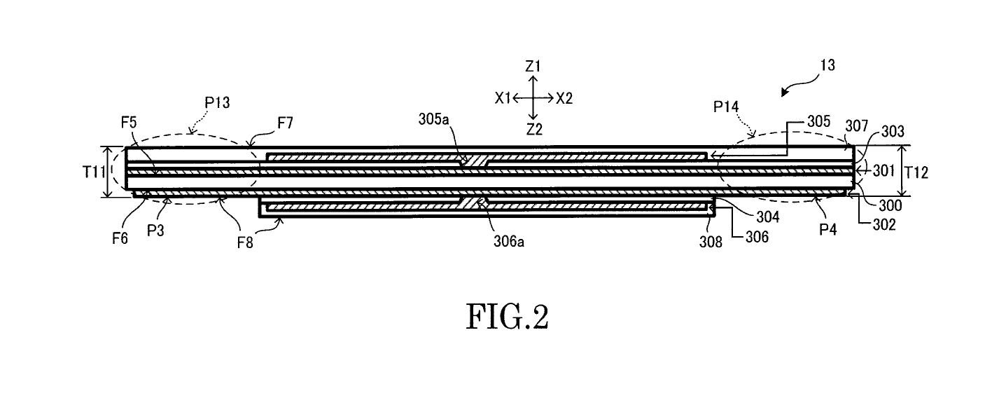

Flexible wiring board 13 is positioned in recessed portion (R30), and each end portion of flexible wiring board 13 is positioned in opening portion (R10) or (R20). FIG. 2 shows a schematic view of flexible wiring board 13.

As shown in FIG. 2, for example, flexible wiring board 13 has flexible substrate 300 (the core substrate of flexible wiring board 13), conductive layers (301, 302), insulation layers (303, 304), shielding layers (305, 306) and coverlays (307, 308). In the following, one (Z1 side) of upper and lower surfaces (two main surfaces) of flexible substrate 300 is referred to as fifth surface (F5) and the other (Z2 side) as sixth surface (F6). In addition, one (Z1 side) of upper and lower surfaces (two main surfaces) of flexible wiring board 13 is referred to as seventh surface (F7) and the other (Z2 side) as eighth surface (F8).

Flexible substrate 300 is made of insulative polyimide or liquid-crystal polymer, for example.

Conductive layer 301 is formed on fifth surface (F5) of flexible substrate 300, and conductive layer 302 is formed on sixth surface (F6) of flexible substrate 300. Conductive layers (301, 302) each include striped wiring which connects wiring in rigid wiring board 11 and wiring in rigid wiring board 12 to each other, for example. Conductive layers (301, 302) are each made of copper, for example.

Insulation layer 303 is formed on conductive layer 301, and insulation layer 304 is formed on conductive layer 302. Insulation layer 303 insulates conductive layer 301 from the outside, and insulation layer 304 insulates conductive layer 302 from the outside. Insulation layers (303, 304) are each made of polyimide, for example.

Shielding layer 305 is formed on insulation layer 303, and shielding layer 306 is formed on insulation layer 304. Shielding layers (305, 306) shield electromagnetic noise from the outside to conductive layers (301, 302) while shielding electromagnetic noise from conductive layers (301, 302) to the outside. Shielding layers (305, 306) are each made of conductive paste, for example. Conductive paste includes silver fine particles, for example.

Via conductor (305a) (filled conductor, for example) is formed in insulation layer 303, and via conductor (306a) (filled conductor, for example) is formed in insulation layer 304. Conductive layer 301 and shielding layer 305 are electrically connected to each other by via conductor (305a). Also, conductive layer 302 and shielding layer 306 are electrically connected to each other by via conductor (306a). Via conductors (305a, 306a) are each formed by filling holes formed in insulation layers (303, 304) with the material of shielding layers (305, 306) (such as conductive paste).

Coverlay 307 is formed on insulation layer 303 and on shielding layer 305, and coverlay 308 is formed on insulation layer 304 and on shielding layer 306. Coverlay 307 covers shielding layer 305, and coverlay 308 covers shielding layer 306. Coverlays (307, 308) insulate as well as protect the entire flexible wiring board 13 from the outside. Coverlays (307, 308) are each made of polyimide, for example.

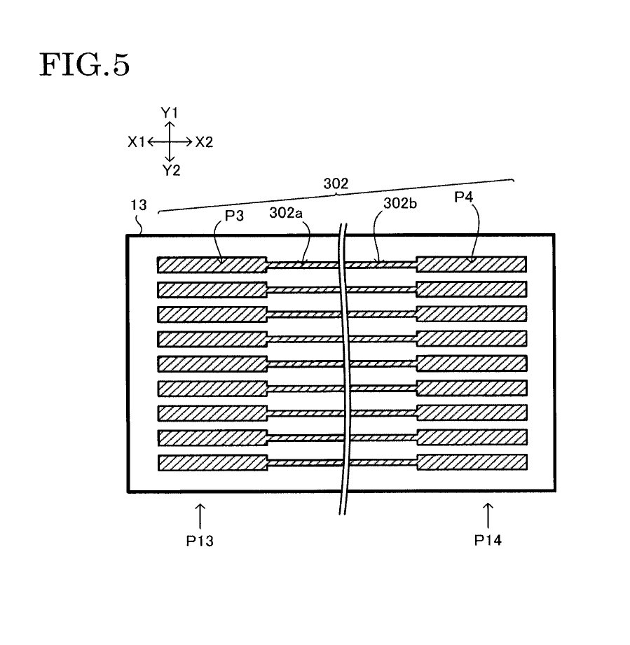

On eighth surface (F8) of flexible wiring board 13, insulation layer 304, shielding layer 306 and coverlay 308 are not formed at end portions (P13, P14), and conductive layer 302 is exposed. Pad (P3) is formed from conductive layer 302 at end portion (P13), and pad (P4) is formed from conductive layer 302 at end portion (P14) (see later-described FIG. 5).

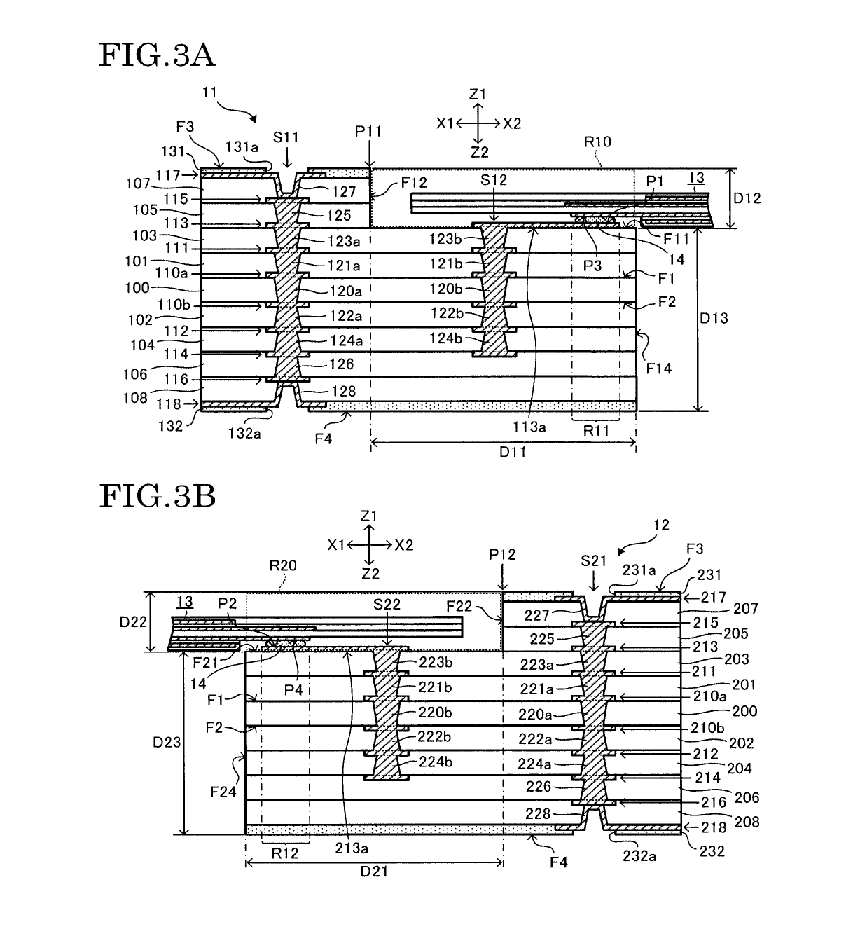

FIGS. 3A and 3B show schematic views of rigid wiring boards (11, 12).

As shown in FIG. 3A, rigid wiring board 11 has insulative substrate 100 (the core substrate of rigid wiring board 11), conductive layers (110a, 110b, 111˜118), insulation layers (101˜108) and solder resists (131, 132). Conductive layer (110a) is formed on first surface (F1) of substrate 100, and conductive layer (110b) is formed on second surface (F2) of substrate 100. On the first-surface (F1) side of substrate 100, insulation layers (101, 103, 105, 107) and conductive layers (111, 113, 115, 117) are alternately laminated; and on the second-surface (F2) side of substrate 100, insulation layers (102, 104, 106, 108) and conductive layers (112, 114, 116, 118) are alternately laminated. Rigid wiring board 11 has solder resist 131 on the outermost layer (insulation layer 107 and conductive layer 117) on the third-surface (F3) side, and has solder resist 132 on the outermost layer (insulation layer 108 and conductive layer 118) on the fourth-surface (F4) side. Opening portions are each formed in solder resists (131, 132), and outermost conductive layers (conductive layers (117, 118)) are exposed through the opening portions to become pads (external connection terminals) respectively.

Via holes are formed in substrate 100, and when such via holes are filled with copper plating, for example, they become via conductors (120a, 120b). Via holes are formed in insulation layers (101, 103, 105, 107), and they become via conductors (121a, 121b, 123a, 123b, 125, 127) when copper plating, for example, is formed in each via hole. Also, via holes are formed in insulation layers (102, 104, 106, 108), and they become via conductors (122a, 122b, 124a, 124b, 126, 128) when copper plating, for example, is formed in each via hole. Outer-layer via conductors (127, 128) are conformal vias, and inner-layer via conductors are filled vias. In rigid wiring board 11 of the present embodiment, via conductors (120a˜124a, 125˜128) in all layers are stacked to form stacked-conductor structure (S11) (vertical wiring portion). Also, via conductors (120b˜124b) are stacked to form stacked-conductor structure (S12) (vertical wiring portion) that includes via conductor (123b) (first conductor).

As shown in FIG. 3B, rigid wiring board 12 has insulative substrate 200 (the core substrate of rigid wiring board 12), conductive layers (210a, 210b, 211˜218), insulation layers (201˜208) and solder resists (231, 232). Conductive layer (210a) is formed on first surface (F1) of substrate 200, and conductive layer (210b) is formed on second surface (F2) of substrate 200. On the first-surface (F1) side of substrate 200, insulation layers (201, 203, 205, 207) and conductive layers (211, 213, 215, 217) are alternately laminated; and on the second-surface (F2) side of substrate 200, insulation layers (202, 204, 206, 208) and conductive layers (212, 214, 216, 218) are alternately laminated. Rigid wiring board 12 has solder resist 231 on the outermost layer (insulation layer 207 and conductive layer 217) on the third-surface (F3) side, and solder resist 232 on the outermost layer (insulation layer 208 and conductive layer 218) on the fourth-surface (F4) side. Opening portions are each formed in solder resists (231, 232), and outermost conductive layers (conductive layers (217, 218)) are exposed through the opening portions to become pads (external connection terminals) respectively.

Via holes are formed in substrate 200, and when such via holes are filled with copper plating, for example, they become via conductors (220a, 220b). Via holes are formed in insulation layers (201, 203, 205, 207), and they become via conductors (221a, 221b, 223a, 223b, 225, 227) when copper plating, for example, is formed in each via hole. Also, via holes are formed in insulation layers (202, 204, 206, 208), and they become via conductors (222a, 222b, 224a, 224b, 226, 228) when copper plating, for example, is formed in each via hole. Outer-layer via conductors (227, 228) are conformal vias, and inner-layer via conductors are filled vias. In rigid wiring board 12 of the present embodiment, via conductors (220a˜224a, 225˜228) in all layers are stacked to form stacked-conductor structure (S21) (vertical wiring portion). Also, via conductors (220b˜224b) are stacked to form stacked-conductor structure (S22) (vertical wiring portion) that includes via conductor (223b) (second conductor).

Substrates (100, 200) are each made by impregnating glass cloth (core material) with epoxy resin (hereinafter referred to as glass epoxy), for example. The core material has a lower thermal expansion coefficient than primary material (epoxy resin in the present embodiment). Inorganic material such as glass fiber (glass cloth or glass non-woven fabric, for example), aramid fiber (aramid non-woven fabric, for example), or silica filler is considered preferable as core material. However, the material of substrates (100, 200) is basically determined freely. For example, polyester resin, bismaleimide triazine resin (BT resin), imide resin (polyimide), phenol resin, allyl polyphenylene ether resin (A-PPE resin) or the like may also be used instead of epoxy resin. Each substrate may be formed with multiple layers having different materials.

Insulation layers (101˜108, 201˜208) are each made of glass epoxy, for example. However, that is not the only option, and the material of insulation layers is basically determined freely. For example, polyester resin, bismaleimide triazine resin (BT resin), imide resin (polyimide), phenol resin, allyl polyphenylene ether resin (A-PPE resin) or the like may also be used instead of epoxy resin. Each insulation layer may be formed with multiple layers having different materials.

Via conductors (120a˜124a, 120b˜124b, 125˜127, 220a˜224a, 220b˜224b, 225˜227) are each made of copper plating, for example. The shape of those via conductors is a tapered column (truncated cone), for example. A via conductor formed in a buildup section tapers with a diameter increasing from substrate 100 or 200 (core substrate) toward its upper layer, for example. However, that is not the only option, and the shape of via conductors may be determined freely.

Conductive layers (110a, 110b, 111˜117, 210a, 210b, 211˜217) are each formed with copper foil (lower layer) and copper plating (upper layer). Such conductive layers include, for example, wiring (inner-layer wiring) that forms electrical circuits, lands, plain patterns for enhancing strength of the wiring board, or the like.

The material of each conductive layer and each via conductor is determined freely as long as it is conductive, and it may be metallic or non-metallic. Each conductive layer and each via conductor may be formed with multiple layers having different materials.

Solder resists (131, 132, 231, 232) are each made of resin, for example, photosensitive resin using acrylic epoxy resin, thermosetting resin containing mainly epoxy resin, UV-curable resin or the like.

Connection terminals of rigid wiring boards (11, 12) and flexible wiring board 13 are described with reference to FIGS. 3A˜6.

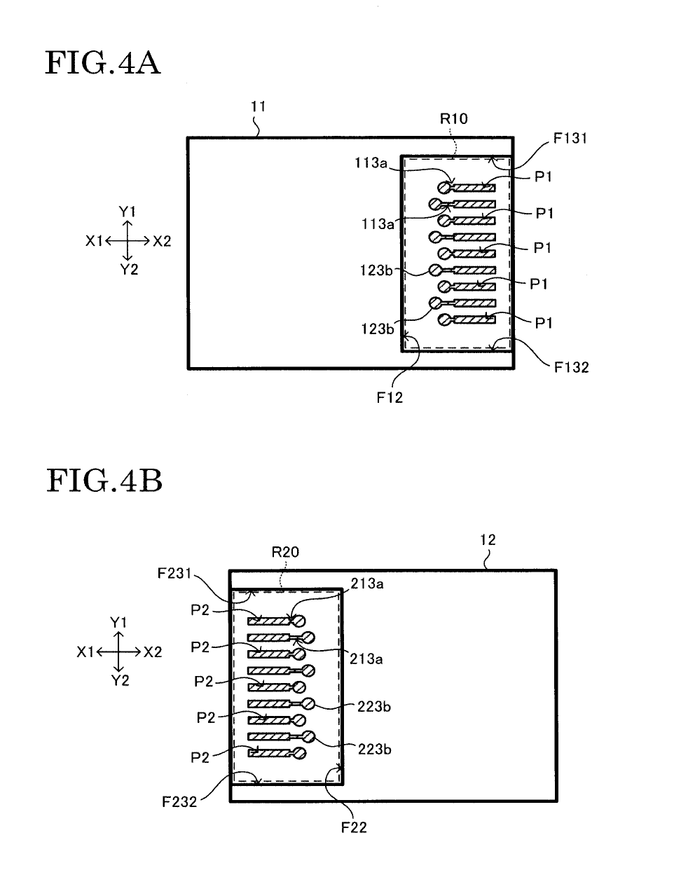

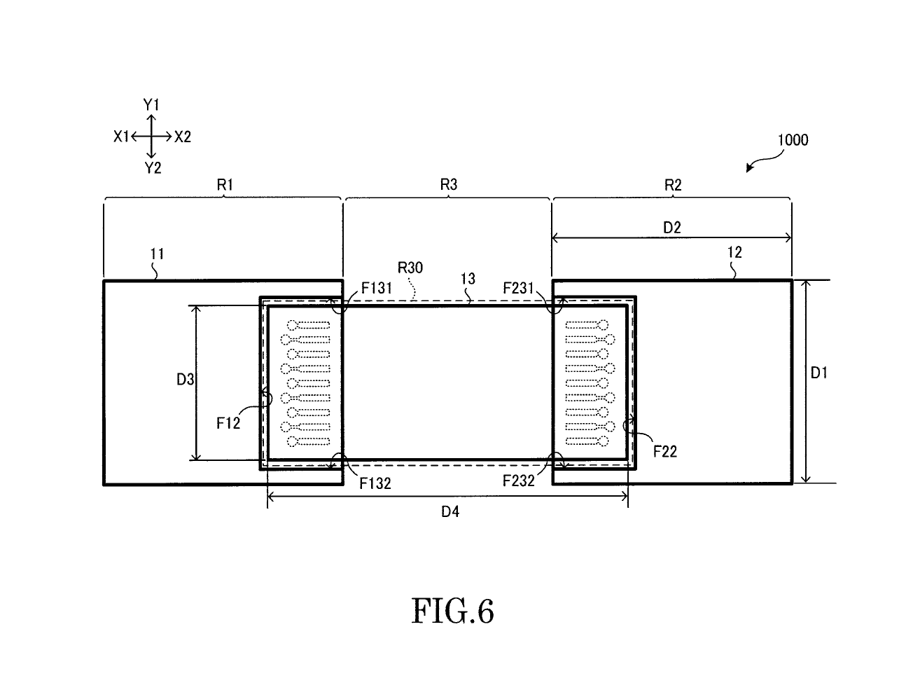

End portions (end portions (P13, P14) shown in FIG. 2) of flexible wiring board 13 are respectively positioned on bottom surfaces (F11, F21) of opening portion (R10), as shown in FIGS. 3A and 3B. Also, both end portions of flexible wiring board 13 are surrounded by U-shaped wall surfaces of opening portions (R10, R20) as shown in FIGS. 4A, 4B (see later-described FIG. 6). Accordingly, it is easier to align flexible wiring board 13. Among the wall surfaces of opening portion (R10), wall surfaces (F12, F22) are positioned on the (X1) side or (X2) side of flexible wiring board 13 (in a longitudinal direction of flexible wiring board 13), facing the end surface of end portion (P13) or (P14) of flexible wiring board 13 (FIG. 2). In addition, wall surfaces (F131, F132) and wall surfaces (F231, F232) are respectively positioned on both sides of flexible wiring board 13 (in a lateral direction of flexible wiring board 13), facing a side surface of end portion (P13) or (P14) of flexible wiring board 13 (FIG. 2).

Step portions (P11, P12) are respectively formed by opening portions (R10, R20) at the surface (on the third-surface (F3) side of the present embodiment) of an inner side of rigid wiring boards (11, 12) (the side facing flexible section (R3)). Bottom surface (F11) of opening portion (R10) corresponds to the lower step of step portion (P11), and bottom surface (F21) of opening portion (R20) corresponds to the lower step of step portion (P12). As shown in FIG. 3A, the inner side surface of rigid wiring board 11 is formed to be a step by wall surface (F12) of opening portion (R10), bottom surface (F11) of opening portion (R10) and side surfaces (F14) of the layers of rigid wiring board 11 where opening portion (R10) is not formed. Also, as shown in FIG. 3B, the inner side surface of rigid wiring board 12 (the side facing flexible section (R13)) is formed to be a step by wall surface (F22) of opening portion (R20), bottom surface (F21) of opening portion (R20) and side surfaces (F24) of the layers of rigid wiring board 12 where opening portion (R20) is not formed.

As shown in FIGS. 3A and 4A, rigid wiring board 11 (first rigid wiring board) has pad (P1) (first connection terminal) formed on bottom surface (F11) of opening portion (R10). Pad (P1) is included in conductive layer 113.

As shown in FIGS. 3B and 4B, rigid wiring board 12 (second rigid wiring board) has pad (P2) (second connection terminal) formed on bottom surface (F21) of opening portion (R20). Pad (P2) is included in conductive layer 213.

As shown in FIG. 5, flexible wiring board 13 has pad (P3) (third connection terminal) and pad (P4) (fourth connection terminal) on a surface. Pad (P3) is connected to a tip of wiring (302a), for example, and pad (P4) is connected to a tip of wiring (302b), for example. Wirings (302a, 302b) and pads (P3, P4) are each included in conductive layer 302.

Rigid wiring board 11 and rigid wiring board 12 are preferred to have symmetrical structures. For example, in FIGS. 3A and 3B, depth (D12) of opening portion (R10) (first opening portion) and depth (D22) of opening portion (R20) (second opening portion) are preferred to be equal. When the difference in connecting situations at both ends of flexible wiring board 13 is reduced, stress is seldom concentrated.

Height (D13) of the mounting surface in rigid wiring board 11 and height (D23) of the mounting surface in rigid wiring board 12 are preferred to be equal. By taking such measurements, it is easier to mount flexible wiring board 13, and electrical connection reliability is enhanced at connecting portions between rigid wiring boards (11, 12) and flexible wiring board 13.

Also, in FIG. 2, thickness (T11) of the portion (end portion (P13)) to position pad (P3) (third connection terminal) in flexible wiring board 13 is preferred to be the same as or less than depth (D12) of opening portion (R10) (first opening portion) (FIG. 3A); and the thickness of the portion (end portion (P14)) to position pad (P4) (fourth connection terminal) in flexible wiring board 13 is preferred to be the same as or less than depth (D22) of opening portion (R20) (second opening portion) (FIG. 3B). By taking such measurements, it is easier to mount flexible wiring board 13, and electrical connection reliability is enhanced at connecting portions between rigid wiring boards (11, 12) and flexible wiring board 13.

In preferred examples, length (D11) of opening portion (R10) and length (D21) of opening portion (R20) are each 3.5 mm, depth (D12) of opening portion (R10) and depth (D22) of opening portion (R20) are each 0.13 mm, thicknesses (T11, T12) of flexible wiring board 13 are each 0.1 mm, and heights (D13, D23) of mounting surfaces of rigid wiring boards (11, 12) are each 0.4 mm. Also, in FIG. 6, width (D1) (measurement in a lateral direction) of rigid wiring board 11 or 12 is 0.05 mm, and length (D2) (measurement in a longitudinal direction) of rigid wiring board 11 or 12 is 0.1 mm. Width (D3) (measurement in a lateral direction) of flexible wiring board 13 is 0.033 mm, and length (D4) (measurement in a longitudinal direction) of flexible wiring board 13 is 56 mm.

Pads (P1˜P4) each have an anticorrosion layer made of Ni/Au film, for example, on their surfaces in the present embodiment. Such an anticorrosion layer is formed by electrolytic plating, sputtering or the like. Also, by performing an OSP treatment, an anticorrosion layer made of organic preservative film may be formed. An anticorrosion layer is not always required, and it may be omitted unless necessary.

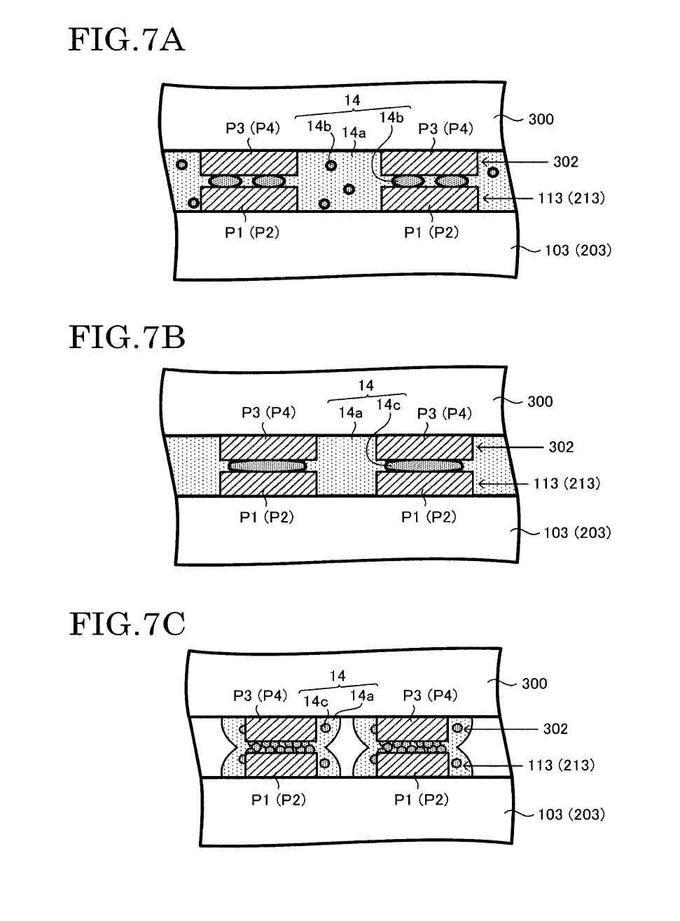

In flex-rigid wiring board 1000 of the present embodiment, flexible wiring board 13 is placed in recessed portion (R30) as shown in FIG. 6. Then, pad (P1) (first connection terminal) and pad (P3) (third connection terminal) as well as pad (P2) (second connection terminal) and pad (P4) (fourth connection terminal) are electrically connected respectively. In the present embodiment, pad (P1) and pad (P3) as well as pad (P2) and pad (P4) are electrically connected to each other by bonding material 14. In the following, preferred examples of bonding material 14 are described with reference to FIGS. 7A-7C.

Bonding material 14 is preferred to be made of ACF (anisotropic conductive film) as shown in FIG. 7A, for example. ACF is made of anisotropic conductive resin. Bonding material 14 shown in FIG. 7A is formed with resin (14a) made of thermosetting resin and conductive particles (14b). Conductive particles (14b) are dispersed in resin (14a). Pad (P1) of rigid wiring board 11 and pad (P3) of flexible wiring board 13 as well as pad (P2) of rigid wiring board 12 and pad (P4) of flexible wiring board 13 are electrically connected respectively by conductive particles (14b), and they are fixed when resin (14a) (thermosetting resin) is cured.

Alternatively, bonding material 14 may be made of conductive resin as shown in FIG. 7B, for example. The conductive resin shown in FIG. 7B is formed with resin (14a) and solder (14c). Here, resin (14a) is made of epoxy resin, for example. Resin (14a) is a flux for solder (14c), for example, and works as underfill. Pad (P1) and pad (P3) as well as pad (P2) and pad (P4) are electrically connected respectively by solder (14c), and they are fixed when solder (14c) is cured.

Alternatively, bonding material 14 may be made of conductive resin as shown in FIG. 7C, for example. The conductive resin shown in FIG. 7C is formed with resin (14a) made of thermosetting resin and solder powder (14c). Here, resin (14a) is a flux for solder (14c) for example. Solder (14c) is dispersed in resin (14a). Pad (P1) and pad (P3) as well as pad (P2) and pad (P4) are electrically connected respectively by solder (14c), and they are fixed when resin (14a) (thermosetting resin) and solder (14c) are cured.

In any example shown in FIGS. 7A˜7C, electrical connecting portions between pads are covered by insulative resin (14a), and short-circuiting or the like is suppressed between adjacent pads.

In flex-rigid wiring board 1000 of the present embodiment, via conductor (123b) (first conductor) for interlayer connection is formed in insulation layer 103 (first insulation layer) in such a way to avoid being directly under pad (P1) (first connection terminal) (region R11) (see FIGS. 1 and 3A). Pads (P1) (see FIG. 4A) are each electrically connected to via conductor (123b) by conductive pattern (113a) (first conductive pattern) of conductive layer 113 formed on insulation layer 103. Since conductive pattern (113a) has higher flexibility than a vertical wiring portion of via conductors or the like, it is easier to mitigate stress exerted on connecting portions between rigid wiring board 11 and flexible wiring board 13 because of elastic deformation of conductive pattern (113a). As a result, connection reliability is enhanced between rigid wiring board 11 and flexible wiring board 13.

Also, via conductor (223b) (second conductor) for interlayer connection is formed in insulation layer 203 (second insulation layer) in such a way to avoid being directly under pad (P2) (second connection terminal) (region R12) (see FIGS. 1 and 3B). Pads (P2) (see FIG. 4B) are each electrically connected to via conductor (223b) by conductive pattern (213a) (second conductive pattern) of conductive layer 213 formed on insulation layer 203. Conductive pattern (213a) has higher flexibility than a vertical wiring portion of via conductors or the like, and it is easier to mitigate stress exerted on connecting portions between rigid wiring board 12 and flexible wiring board 13 because of elastic deformation of conductive pattern (213a). As a result, connection reliability is enhanced between rigid wiring board 12 and flexible wiring board 13.

In the present embodiment, pads (P1) are each electrically connected to via conductor (123b) by conductive pattern (113a) (first conductive pattern) of conductive layer 113 formed on insulation layer 103. Also, pads (P2) are each electrically connected to via conductor (223b) by conductive pattern (213a) (second conductive pattern) of conductive layer 213 formed on insulation layer 203. Accordingly, the effect of mitigating stress as described above is achieved in all pads (P1, P2). Also, by eliminating a concentration of stress, a multiplier effect is expected. However, the present embodiment is not limited to such, and instead of all pads (P1) or all pads (P2), if at least one pad (P1) or (P2) is electrically connected to via conductor (123b) or (223b) by conductive pattern (113a) or (213a), it is sufficient to achieve certain effects.

In the present embodiment, via conductor (123b) of rigid wiring board 11 (first conductor) and via conductor (223b) of rigid wiring board 12 (second conductor) are formed to be positioned directly under flexible wiring board 13 (region R13).

In the present embodiment, via conductor (123b) of rigid wiring board 11 (first conductor) and via conductor (223b) of rigid wiring board 12 (second conductor) are formed in such a way to avoid being the inner sides of step portions (P11, P12) (lower-step region R14). Since rigid wiring board 11 or 12 is thin at lower-step region (R14), via connection reliability tends to be low. For that matter, in flex-rigid wiring board 1000 of the present embodiment, a via conductor, which is formed outside lower-step portion (R14) in rigid wiring board 11 or 12 (upper-step region), and pad (P3) or (P4) of flexible wiring board 13 are electrically connected to each other by conductive pattern (113a) or (213a). Accordingly, electrical connection reliability is enhanced.

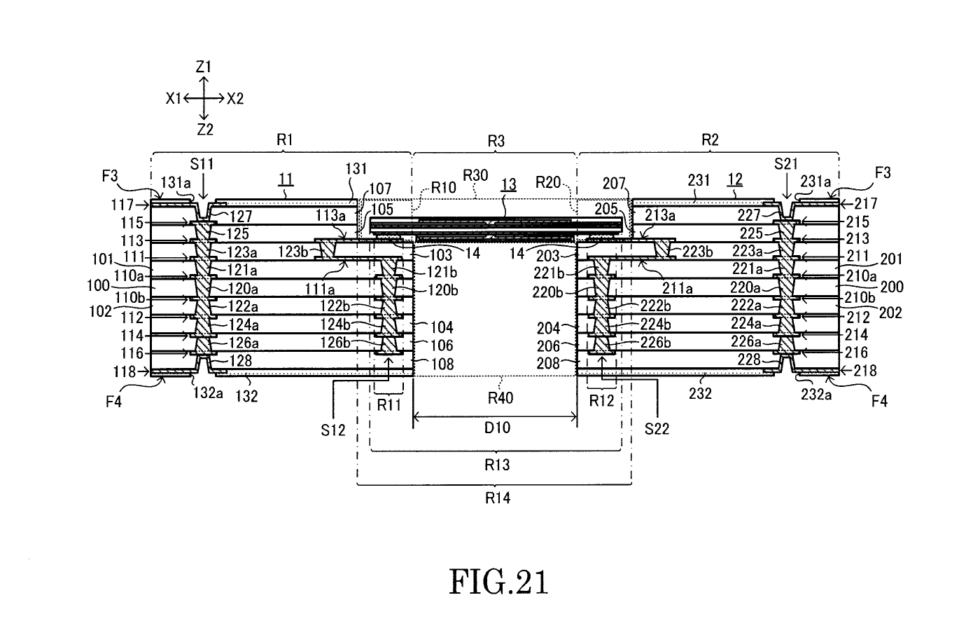

In the present embodiment, via conductors in all layers of rigid wiring board 11 are formed in such a way to avoid being directly under pad (P1) (region R11), and via conductors in all layers of rigid wiring board 12 are formed in such a way to avoid being directly under pad (P2) (region R12). However, that is not the only option, and via conductors in some layers may be formed directly under pad (P1) or (P2) (see later-described FIG. 21).

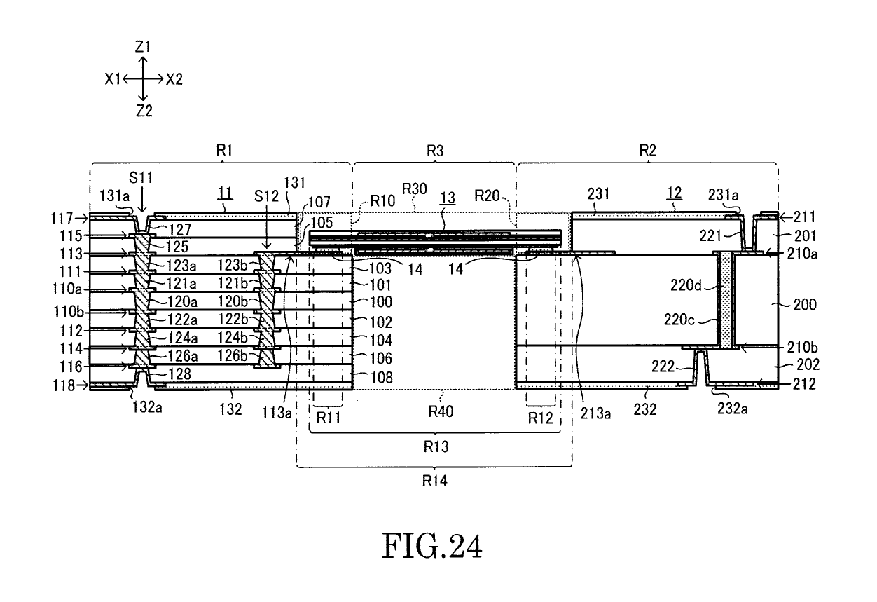

In the present embodiment, the number of conductive layers in rigid wiring board 11 is the same as that in rigid wiring board 12 (both have nine layers). However, that is not the only option, and the number of layers may be different (see later-described FIG. 24).

A method for manufacturing flex-rigid wiring board 1000 according to the present embodiment is described in the following.

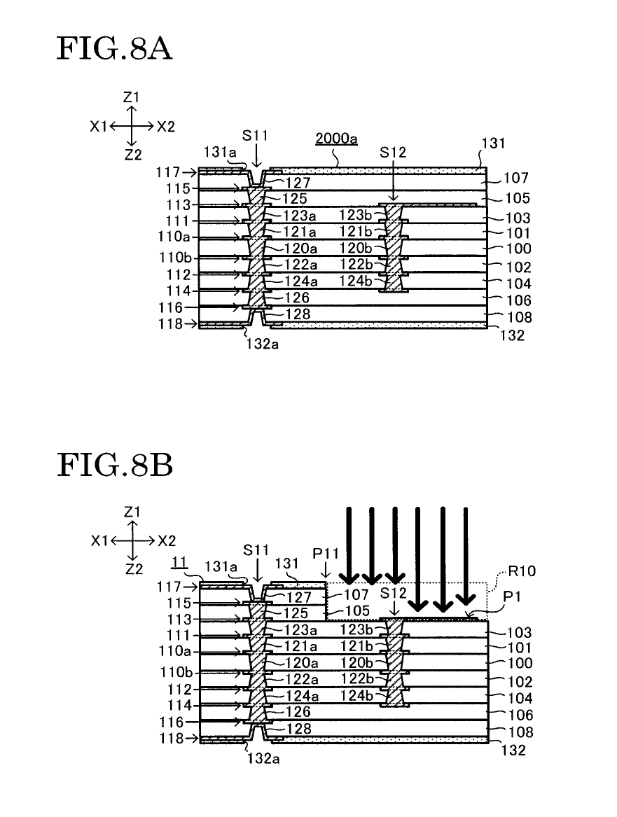

First, rigid wiring board 11 having opening portion (R10), rigid wiring board 12 having opening portion (R20) and flexible wiring board 13 are prepared. In the following, their manufacturing methods are described with reference to FIGS. 8A˜11.

First, rigid wiring board (2000a) as shown in FIG. 8A is prepared. Rigid wiring board (2000a) is a multilayer printed wiring board, which is obtained, for example, by starting with a double-sided copper-clad laminate, alternately laminating insulation layers and conductive layers, connecting between conductive layers with via conductors, and forming solder resist on the outermost layers.

Insulation layers are formed by vacuum lamination using thermosetting prepreg, for example. However, that is not the only option. For example, thermoplastic resin or RCF (resin-coated copper foil) may also be used, or insulation layers may be adhered by pressing.

Conductive layers may be formed by any one of the following methods or a combination of two or more of those: panel plating, pattern plating, full-additive, semi-additive (SAP), subtractive, and tenting methods.

Via conductors are formed, for example, by using a laser to form holes in insulation layers, and by filling conductor in such holes by plating for forming conductive layers.

Solder resist is formed by screen printing, spray coating, roll coating, lamination or the like, for example.

Next, as shown in FIG. 8B, using a laser, for example, opening portion (R10) is formed in rigid wiring board (2000a). Then, desmearing is conducted on opening portion (R10) using chemical agents, plasma, UV rays or the like depending on requirements. Accordingly, rigid wiring board 11 having opening portion (R10) is formed. However, the method for forming opening portion (R10) is not limited to using a laser, and a router or the like may also be used.

Rigid wiring board 12 is manufactured the same as rigid wiring board 11.

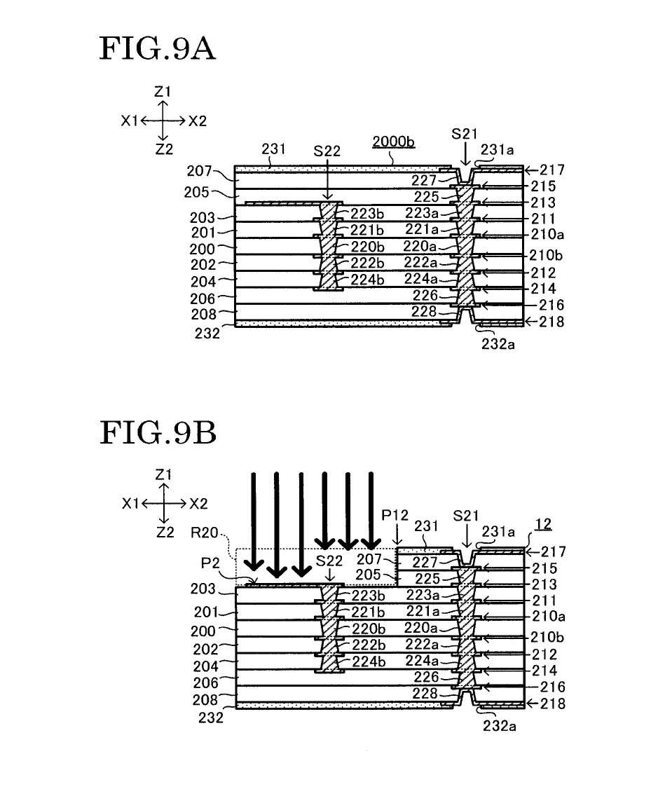

First, rigid wiring board (2000b) as shown in FIG. 9A is prepared. Rigid wiring board (2000b) is a multilayer printed wiring board, and is manufactured by the same method as that for forming rigid wiring board (2000a), for example.

Next, as shown in FIG. 9B, using a laser or the like, opening portion (R20) is formed in rigid wiring board (2000b) to obtain rigid wiring board 12 having opening portion (R20).

Flexible wiring board 13 is obtained by starting with flexible substrate 300, and by forming conductive layers (301, 302), insulation layers (303, 304), via conductors (305a, 306a), shielding layers (305, 306) and coverlays (307, 308) in that order. Conductive layers, insulation layers and via conductors are formed the same as those in rigid wiring board 11, for example. Shielding layers (305, 306) are each formed by screen printing, for example. Coverlays (307, 308) are respectively adhered to insulation layers (303, 304) using adhesives or the like.

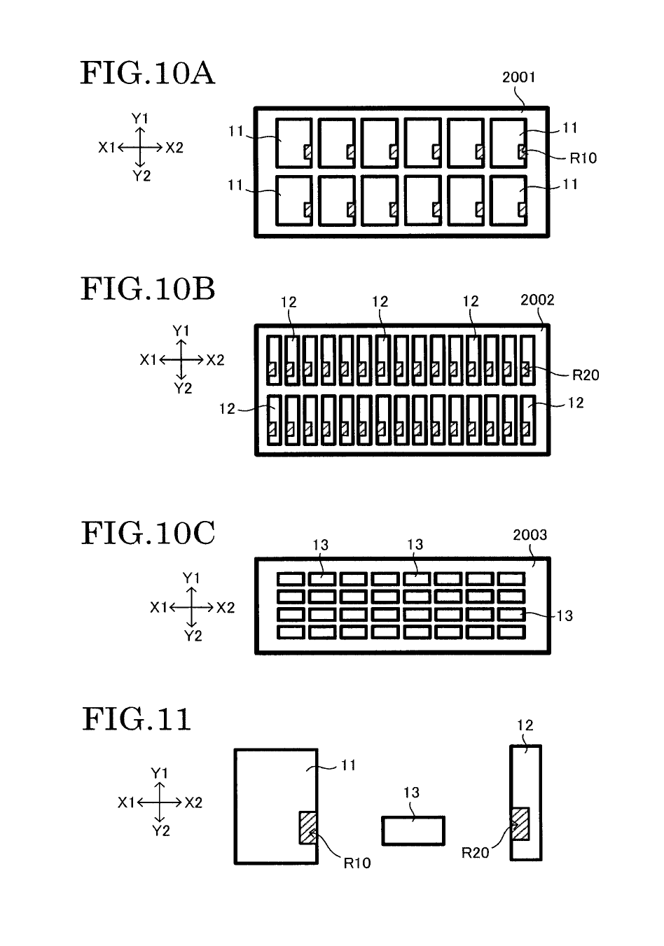

In the present embodiment, multiple rigid wiring boards 11 (first rigid wiring boards) are collectively formed in one panel 2001 in an integrated fashion as shown in FIG. 10A. Also, multiple rigid wiring boards 12 (second rigid wiring boards) are collectively formed in one panel 2002 in an integrated fashion as shown in FIG. 10B. Moreover, multiple flexible wiring boards 13 are collectively formed in one panel 2003 in an integrated fashion as shown in FIG. 10C.

Then, using a router, for example, predetermined wiring boards are separated from the assemblies (panels 2001˜2003) where multiple wiring boards are collectively formed. Accordingly, rigid wiring boards (11, 12) and flexible wiring board 13 are each obtained as an individual unit as shown in FIG. 11.

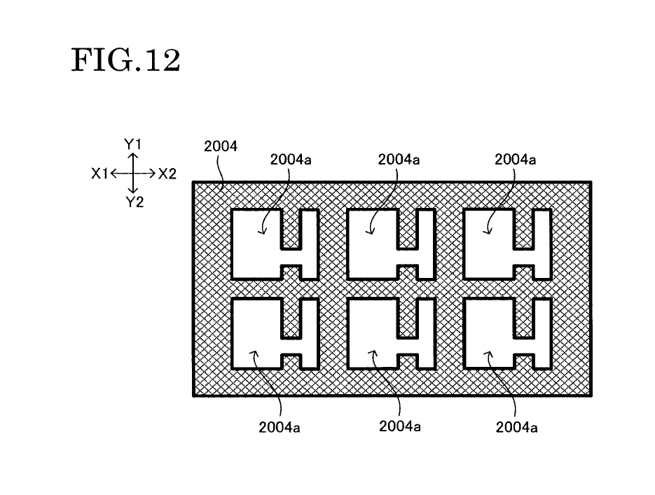

Next, frame 2004 is prepared as shown in FIG. 12, and rigid wiring boards (11, 12) are connected to frame 2004.

Specifically, a laser or a router is used to form opening portion (2004a) in a sheet-type frame 2004, for example, as shown in FIG. 12. Next, rigid wiring boards (11, 12) are positioned in opening portion (2004a) of frame 2004. Then, rigid wiring boards (11, 12) are each connected to frame 2004.

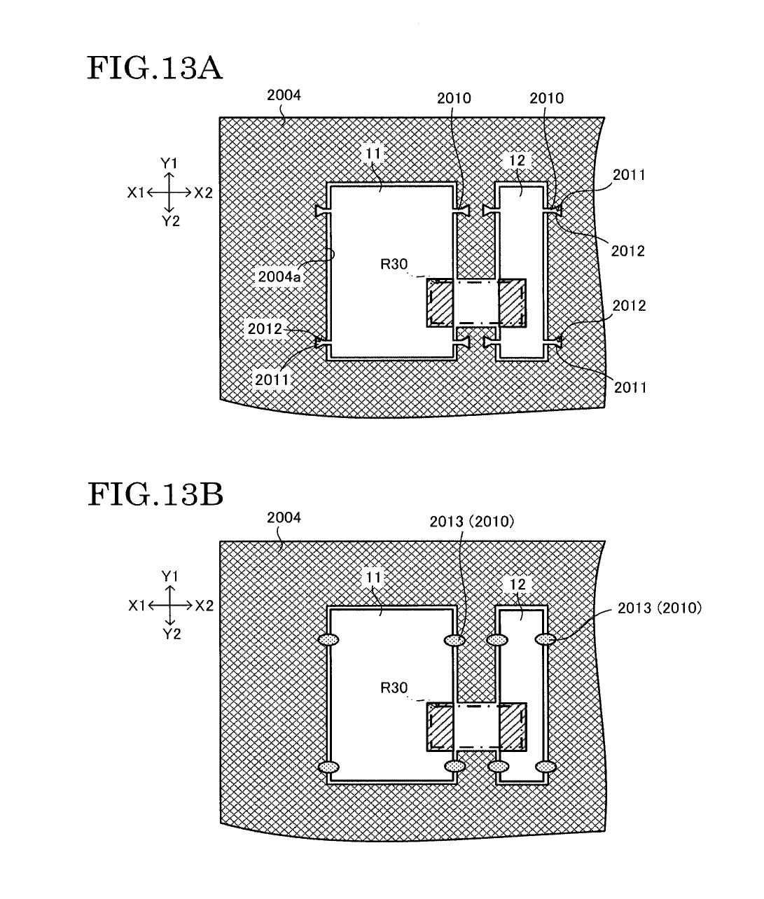

As shown in FIG. 13A, rigid wiring board 11 or 12 and frame 2004 may be connected by forming claw 2011 (protrusion) in either one and forming receptor 2012 (recess) in the other and by fitting claw 2011 into receptor 2012. In the example of FIG. 13A, claw 2011 is formed in rigid wiring board 11 or 12 and receptor 2012 is formed in frame 2004. Inversely, it is an option to form receptor 2012 in rigid wiring board 11 or 12 and claw 2011 in frame 2004. Claw 2011 and receptor 2012 may be formed when cutting out individual units (see FIG. 11), for example. Here, methods for connecting rigid wiring board 11 or 12 and frame 2004 are not limited to fitting (using friction), and any other methods may be used. For example, as shown in FIG. 13b, rigid wiring board 11 or 12 and frame 2004 may be connected by adhesive 2013. In addition, adhesives or the like may further be used as reinforcement after fitting.

The material for frame 2004 may be insulative such as resin, or metallic such as copper.

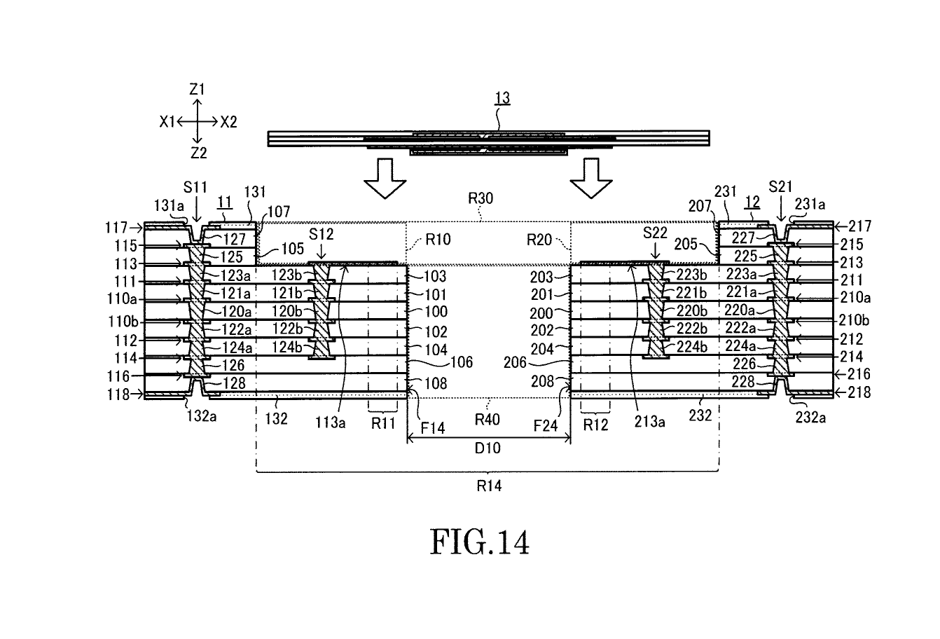

When rigid wiring boards (11, 12) are connected to frame 2004, rigid wiring board 11 and rigid wiring board 12 are positioned at distance (D10) in direction X, for example, as shown in FIG. 14. Accordingly, opening portion (R10) faces opening portion (R20) so that recessed portion (R30) is formed by opening portions (R10, R20) on surfaces of rigid wiring boards (11, 12). Also, a gap is formed between opposing side surfaces (F14, F24) so that opening portion (R40) is formed to be connected to recessed portion (R30).

Next, flexible wiring board 13 is positioned in recessed portion (R30), and pad (P1) of rigid wiring board 11 and pad (P3) of flexible wiring board 13 as well as pad (P2) of rigid wiring board 12 and pad (P4) of flexible wiring board 13 are electrically connected respectively (see FIGS. 7A˜7C). Pad (P1) and pad (P3) as well as pad (P2) and pad (P4) are preferred to be connected at the same time. By simultaneously connecting those pads, it is easier to set connection conditions, and manufacturing efficiency is also enhanced. However, that is not the only option, and pads may be connected separately.

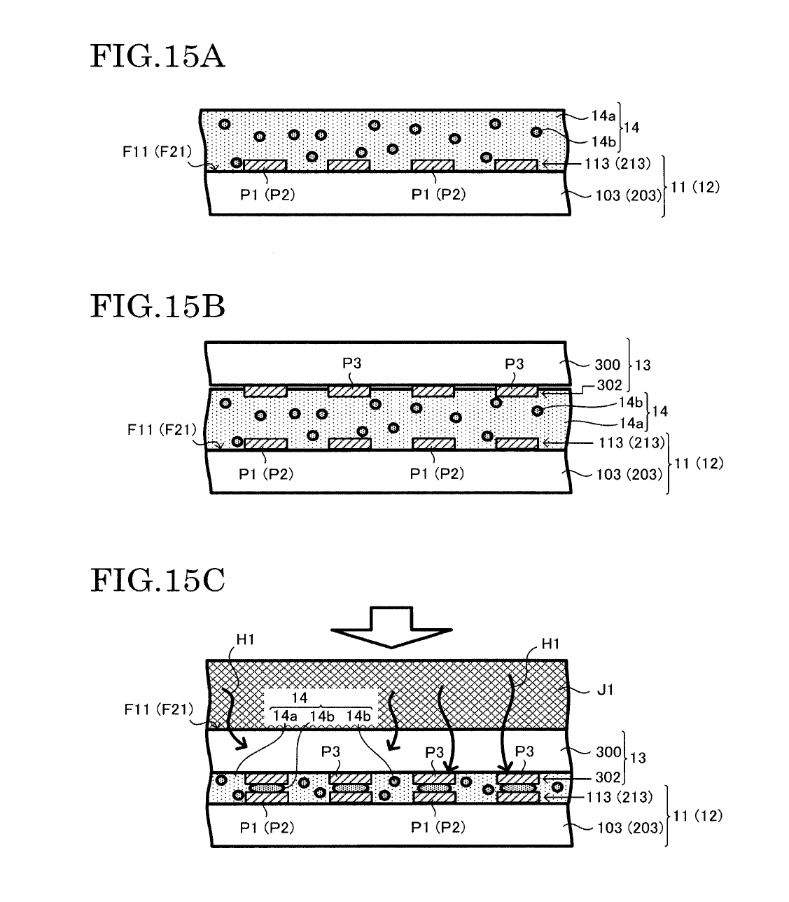

Here, if bonding material 14 is made of ACF (see FIG. 7A), bonding material 14 is formed on bottom surface (F11) of opening portion (R10) in rigid wiring board 11 by lamination, for example, as shown in FIG. 15A. Bonding material 14 is made by dispersing conductive particles (14b) in resin (14a). Next, as shown in FIG. 15B, flexible wiring board 13 is preliminarily adhered to bonding material 14. Next, as shown in FIG. 15C, flexible wiring board 13 is pressed to rigid wiring board 11 using crimp jig (J1). Accordingly, pressure is added from both sides by pad (P1) of rigid wiring board 11 and pad (P3) of flexible wiring board 13 to compress conductive particles (14b). Also, at the same time as crimping or after crimping, bonding material 14 is heated. In FIG. 15C, arrow (H1) indicates thermal conduction. Accordingly, bonding material 14 (thermosetting resin) is cured. As a result, pad (P1) of rigid wiring board 11 and pad (P3) of flexible wiring board 13 are electrically connected to each other by bonding material 14 (in particular, by conductive particles 14b). Pad (P2) of rigid wiring board 12 and pad (P4) of flexible wiring board 13 are also electrically connected the same as in rigid wiring board 11.

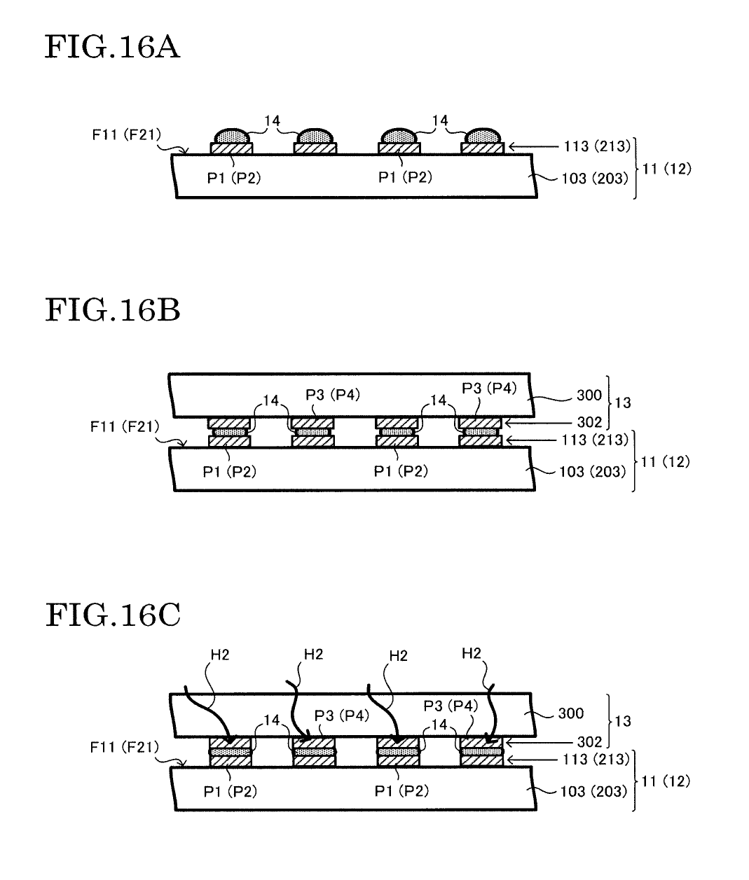

Alternatively, if bonding material 14 is made of solder (see FIGS. 7B, 7C), bonding material 14 made of solder and flux (resin) is formed on pad (P1) of rigid wiring board 11 by printing, for example, as shown in FIG. 16A. Next, as shown in FIG. 16B, flexible wiring board 13 is mounted on rigid wiring board 11. Accordingly, pad (P1) of rigid wiring board 11 and pad (P3) of flexible wiring board 13 are electrically connected to each other by bonding material 14 (solder, in particular). Next, as shown in FIG. 16C, a reflow is conducted to heat bonding material 14. Arrow (H2) in FIG. 16C indicates thermal conduction. Accordingly, the solder is cured. When flux is made of thermosetting resin, the flux is also cured by heat. As a result, wiring boards are fixed in such a way as shown in FIG. 7B or 7C. Pad (P2) of rigid wiring board 12 and pad (P4) of flexible wiring board 13 are also electrically connected the same as in rigid wiring board 11. The methods for connecting pads are not limited to the above, and pads may also be connected to each other by ultrasonic bonding, for example.

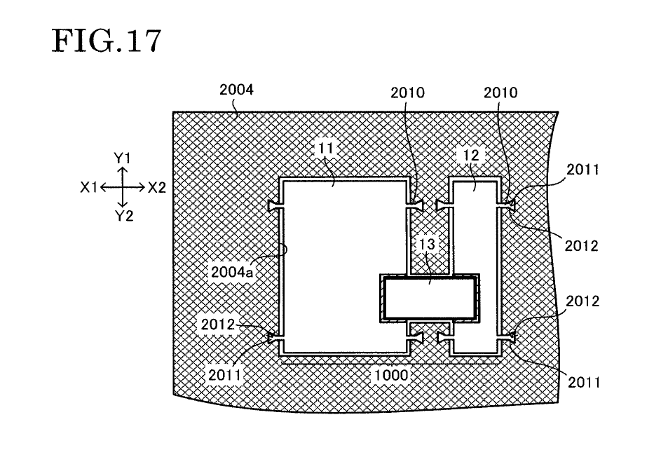

Through the above procedures, flex-rigid wiring board 1000 of the present embodiment is completed (FIG. 1). In the present embodiment, flex-rigid wiring board 1000 is connected to frame 2004 as shown in FIG. 17. It is easy to cut connecting portions (bridges 2010) of rigid wiring board 11 or 12 and frame 2004. By connecting flex-rigid wiring board 1000 to frame 2004, handling of flex-rigid wiring board 1000 becomes easier.

Another wiring board, electronic component or the like may be mounted on surfaces of flex-rigid wiring board 1000. Flex-rigid wiring board 1000 may be used as a circuit board for a cell phone or other mobile device.

The manufacturing method according to the present embodiment includes preparing rigid wiring board 11 (first rigid wiring board); preparing rigid wiring board 12 (second rigid wiring board); preparing flexible wiring board 13; positioning rigid wiring board 11 and rigid wiring board 12 to be spaced apart; positioning flexible wiring board 13 in recessed portion (R30), which is formed by setting opening portion (R10) of rigid wiring board 11 (first opening portion) to face opening portion (R20) of rigid wiring board 12 (second opening portion); and electrically connecting pad (P1) of rigid wiring board 11 (first connection terminal) and pad (P3) of flexible wiring board 13 (third connection terminal) as well as pad (P2) of rigid wiring board 12 (second connection terminal) and pad (P4) of flexible wiring board 13 (fourth connection terminal). In such a manufacturing method, since flexible wiring board 13 is connected last, even when heights (D13, D23) of mounting surfaces (FIGS. 3A, 3B) are different in rigid wiring boards (11, 12), such a height difference is offset by the flexibility of flexible wiring board 13. Accordingly, it is easier to secure electrical connection reliability at connecting portions between rigid wiring boards (11, 12) and flexible wiring board 13.

### Second Embodiment

A second embodiment of the present invention is described focusing on the differences with the above first embodiment. Here, the same reference number is used for an element identical to the element shown in FIG. 1 and others above, and a common portion already described, namely, the portion whose description would be redundant, is omitted or simplified.

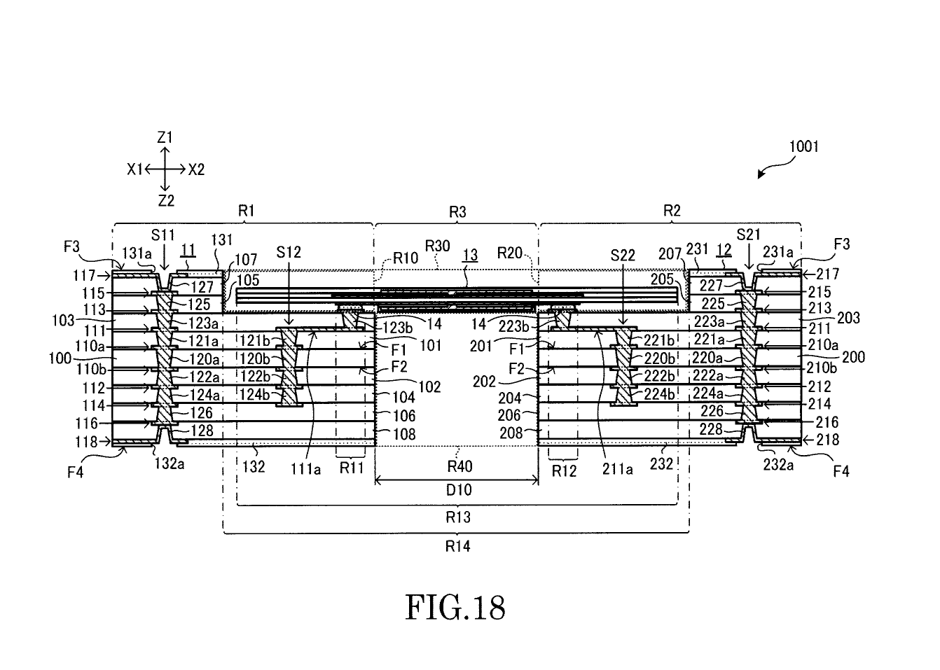

FIGS. 18˜19B schematically show flex-rigid wiring board 1001 according to the present embodiment.

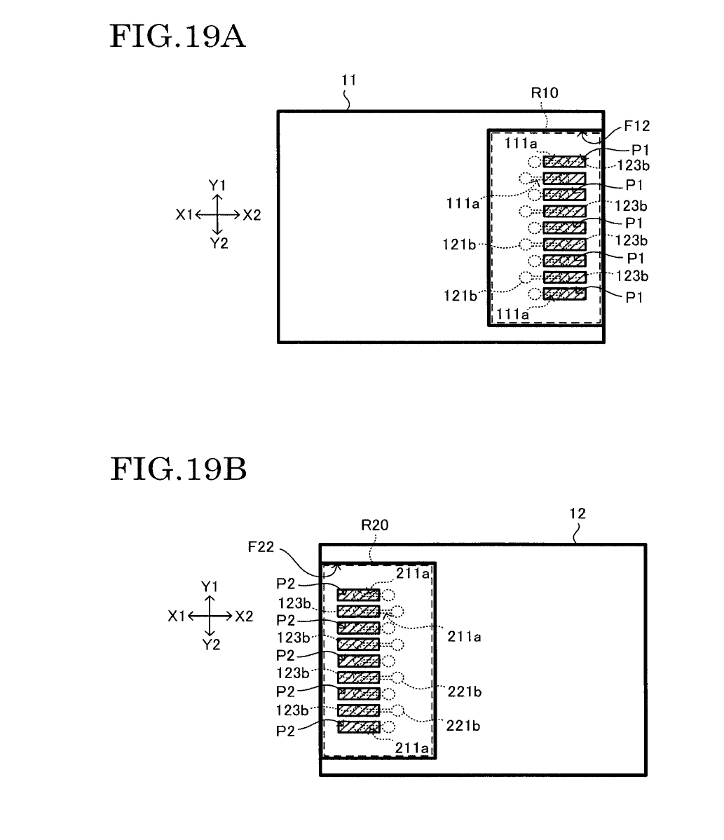

In flex-rigid wiring board 1001 according to the present embodiment, via conductor (123b) of rigid wiring board 11 is formed directly under pad (P1) (region R11) as shown in FIGS. 18 and 19A, and via conductor (223b) of rigid wiring board 12 is formed directly under pad (P2) (region R12) as shown in FIGS. 18 and 19B.

On the other hand, via conductor (121b) (first conductor) for interlayer connection is formed in lower insulation layer 101 of insulation layer 103 (first insulation layer) in such a way to avoid being directly under pad (P1) (first connection terminal) (region R11). In the present embodiment, pads (P1) are each electrically connected to via conductor (121b) through via conductor (123b) formed in insulation layer 103 and conductive pattern (111a) of conductive layer 111 (first conductive pattern) formed on insulation layer 101. Since conductive pattern (111a) is highly flexible, it is easier to mitigate stress exerted on connecting portions between rigid wiring board 11 and flexible wiring board 13 because of elastic deformation of conductive pattern (111a). As a result, connection reliability is enhanced between rigid wiring board 11 and flexible wiring board 13. Here, instead of all pads (P1), if at least one of pads (P1) is electrically connected to via conductor (121b) through via conductor (123b) and conductive pattern (111a), it is sufficient to achieve certain effects.

Also, via conductor (221b) (second conductor) for interlayer connection is formed in lower insulation layer 201 of insulation layer 203 (second insulation layer) in such a way to avoid being directly under pad (P2) (second connection terminal) (region R12). Pads (P1) are each electrically connected to via conductor (221b) through via conductor (223b) formed in insulation layer 203 and conductive pattern (211a) (second conductive pattern) of conductive layer 211 formed on insulation layer 201. Since conductive pattern (211a) is highly flexible, it is easier to mitigate stress exerted on connecting portions between rigid wiring board 12 and flexible wiring board 13 because of elastic deformation of conductive pattern (211a). As a result, connection reliability is enhanced between rigid wiring board 12 and flexible wiring board 13. Here, instead of all pads (P2), if at least one of pads (P2) is electrically connected to via conductor (221b) through via conductor (223b) and conductive pattern (211a), it is sufficient to achieve certain effects.

In the present embodiment, via conductors (120b˜122b, 124b) are stacked to form stacked-conductor structure (S12) in rigid wiring board 11. Also, via conductors (220b˜222b, 224b) are stacked to form stacked-conductor structure (S22) in rigid wiring board 12.

Flex-rigid wiring board 1001 according to the present embodiment is manufactured by a manufacturing method which is substantially the same as that described in the first embodiment. The position of a via conductor is easily modified by changing the laser irradiation position when forming a hole (via hole) in an insulation layer.

The manufacturing method according to the present embodiment is suitable for manufacturing flex-rigid wiring board 1001. Using such a manufacturing method, excellent, low-cost flex-rigid wiring boards 1001 are produced. Also, regarding the structures and treatments the same as in the first embodiment, substantially the same effects are achieved in the present embodiment as those in the first embodiment.

### Other Embodiments

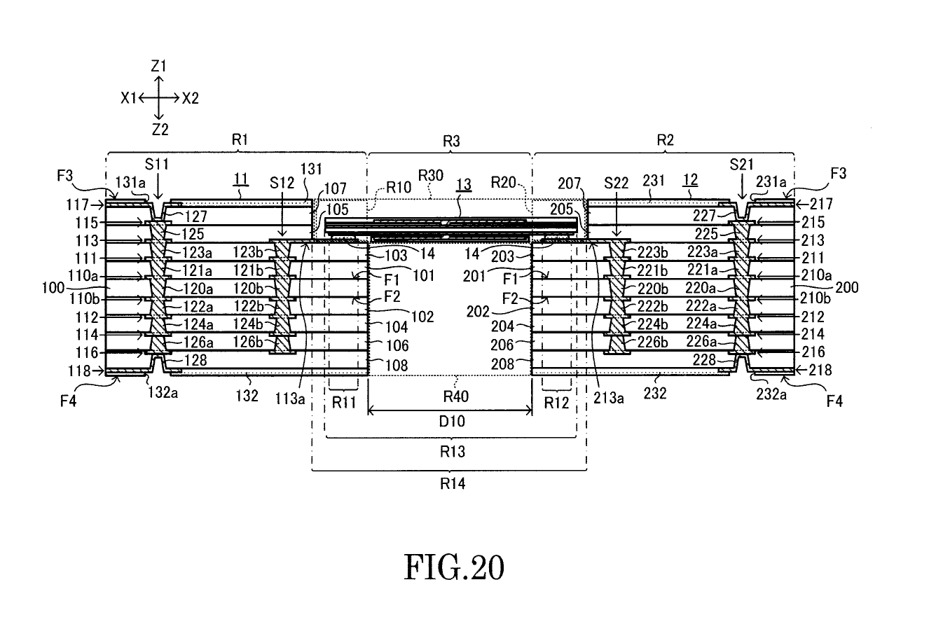

In flex-rigid wiring board 1000 of the first embodiment, it is an option for via conductor (123b) (first conductor) in rigid wiring board 11 and via conductor (223b) (second conductor) in rigid wiring board 12 to be formed in such a way to avoid being directly under flexible wiring board 13 (region R13) (namely, to be outside of the region) as shown in FIG. 20, for example. Also, regarding flex-rigid wiring board 1001 of the second embodiment, it is an option for via conductor (121b) (first conductor) in rigid wiring board 11 and via conductor (221b) (second conductor) in rigid wiring board 12 to be formed in such a way to avoid being directly under flexible wiring board 13 (region R13) (namely, to be outside of the region).

It is also an option for a flex-rigid wiring board to include laminated sections (buildup sections) having a different number of layers on the third-surface (F3) side and on the fourth-surface (F4) side of a core substrate as shown in FIG. 20. In the example in FIG. 21, one layer each (insulation layer 108 and conductive layer 118, insulation layer 208 and conductive layer 218) is omitted from the laminated sections on the fourth-surface (F4) side of substrates (100, 200) (core substrates) in flex-rigid wiring board 1000 of the first embodiment. However, that is not the only option, and the number of layers in laminated sections may be determined freely on the third-surface (F3) side and on the fourth-surface (F4) side of a core substrate. Also, in flex-rigid wiring board 1001 of the second embodiment, part of the laminated sections (for example, insulation layer 108 and conductive layer 118, insulation layer 208 and conductive layer 218) may be omitted from the third-surface (F3) side or the fourth-surface (F4) side of substrates (100, 200) (core substrates).

In flex-rigid wiring board 1000 of the first embodiment above, stacked-conductor structure (S12) including via conductor (123b) (first conductor) or stacked-conductor structure (S22) including via conductor (223b) (second conductor) is formed in such a way to avoid being directly under pad (P1) (first connection terminal) or pad (P2) (second connection terminal) (region R11 or R12) (see FIG. 1). However, that is not the only option. For example, as shown in FIG. 21, via conductors (123b, 223b) may be excluded from stacked-conductor structures (S12, S22), and be positioned in such a way to avoid being directly under pads (P1, P2) (see FIGS. 4A, 4B) (regions (R11, R12)), while stacked-conductor structures (S11, S12) formed by other via conductors are positioned directly under pads (P1, P2) (regions (R11, R12)). In the example in FIG. 21, since pad (P1) or (P2) (see FIGS. 4A, 4B) is connected to stacked-conductor structure (S12) or (S22) through via conductor (123b) or (223b) and conductive patterns (113a, 111a) in multiple layers or conductive patterns (213a, 211a) in multiple layers, stress is expected to be mitigated because of even higher flexibility.

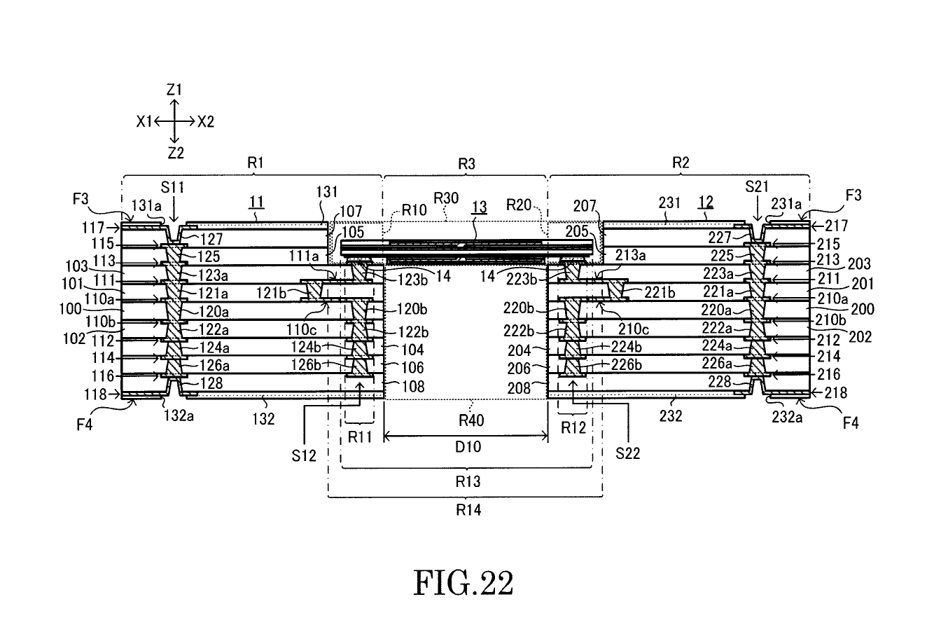

In flex-rigid wiring board 1001 of the second embodiment above, stacked-conductor structure (S12) including via conductor (121b) (first conductor) or stacked-conductor structure (S22) including via conductor (221b) (second conductor) is formed in such a way to avoid being directly under pad (P1) (first connection terminal) or pad (P2) (second connection terminal) (region R11 or R12) (see FIG. 18). However, that is not the only option. For example, as shown in FIG. 22, via conductors (121b, 221b) may be excluded from stacked-conductor structures (S12, S22) and be positioned in such a way to avoid being directly under pads (P1, P2) (regions (R11, R12)), while stacked-conductor structures (S12, S22) formed by other via conductors are positioned directly under pads (P1, P2) (regions (R11, R12)). In the example in FIG. 22, since pad (P1) or (P2) (see FIGS. 19A, 19B) is connected to stacked-conductor structure (S12) or (S22) through via conductors (123b,121b) or via conductors (223b, 221b) and conductive patterns (111a, 110c) in multiple layers or conductive patterns (211a, 210c) in multiple layers, stress is expected to be mitigated because of even higher flexibility.

As shown in FIG. 21, it is an option for via conductors (123b, 223b) not to be stacked and to be electrically connected to lower conductors for interlayer connection (via conductors (121b, 221b)) through conductive patterns (111a, 211a) formed on insulation layers (101, 201) (interlayer insulation layers). Alternatively, as shown in FIG. 22, it is an option for via conductors (121b, 221b) not to be stacked and to be electrically connected to lower conductors for interlayer connection (via conductors (120b, 220b)) through conductive patterns (110a, 210a) formed on substrates (100, 200) (interlayer insulation layers).

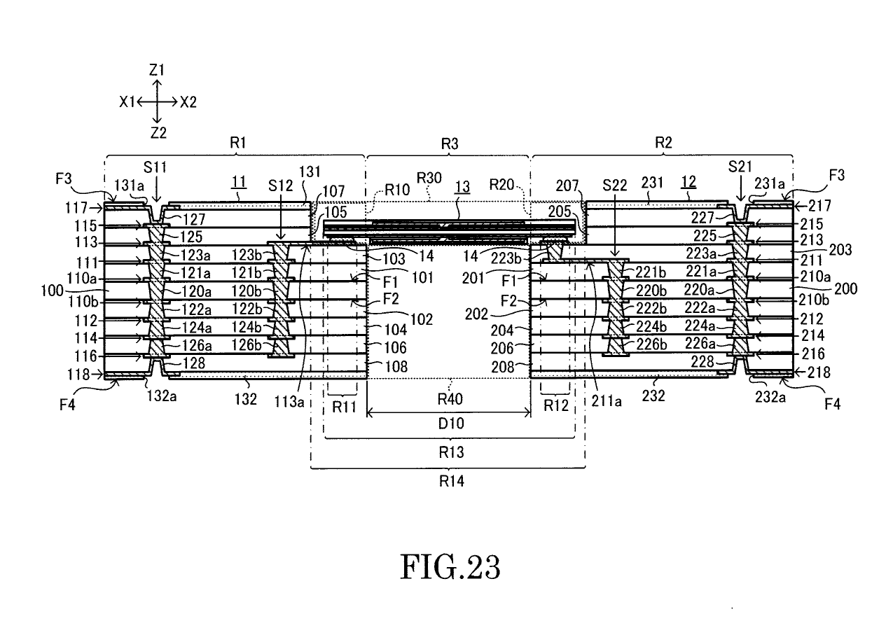

As shown in FIG. 23, it is also an option for rigid wiring board 11 (first rigid wiring board) of flex-rigid wiring board 1000 according to the above first embodiment to be combined with rigid wiring board 12 (second rigid wiring board) of flex-rigid wiring board 1001 according to the above second embodiment.

As shown in FIG. 24, the number of conductive layers may be different in rigid wiring board 11 (first rigid wiring board) and rigid wiring board 12 (second rigid wiring board). In the example in FIG. 24, rigid wiring board 11 has nine conductive layers (110a, 110b, 111˜117) while rigid wiring board 12 has four conductive layers (210a, 210b, 211, 212). In addition, of rigid wiring board 11 and rigid wiring board 12, conductors for interlayer connection in the entire layer are stacked at least in one location of rigid wiring board 11 which has a greater number of conductive layers.

In a flex-rigid wiring board in each embodiment above, flexible wiring board 13 is positioned in recessed portion (R30), which is formed by setting opening portion (R10) in rigid wiring board 11 to face opening portion (R20) in rigid wiring board 12. Accordingly, compared with a flex-rigid wiring board where buildup sections are laminated on both end portions of a flexible wiring board positioned in a side direction of a core substrate, it is more flexible when designing the number of layers or the like of rigid wiring boards. Thus, it is easier to form a flex-rigid wiring board with rigid wiring board 11 and rigid wiring board 12 having a different number of conductive layers (see FIG. 24, for example).

In addition, in the example in FIG. 24, opening portion (R20) (second opening portion) reaches inner substrate 200 (first insulation layer), and through-hole conductor (220c) (first conductor) for interlayer connection is formed in substrate 200 in such a way to avoid being directly under pad (P2) (see FIG. 4B) (region R12). Through-hole conductor (220c) is formed on the wall surface of a hole that penetrates through substrate 200, and insulator (220d) is filled inside. With such a structure as well, since through-hole conductor (220c) is formed in such a way to avoid being directly under pad (P2) (region R12), it is easier to mitigate stress exerted on connecting portions between rigid wiring board 12 and flexible wiring board 13 because of elastic deformation of conductive pattern (213a). As a result, connection reliability is enhanced between rigid wiring board 12 and flexible wiring board 13.

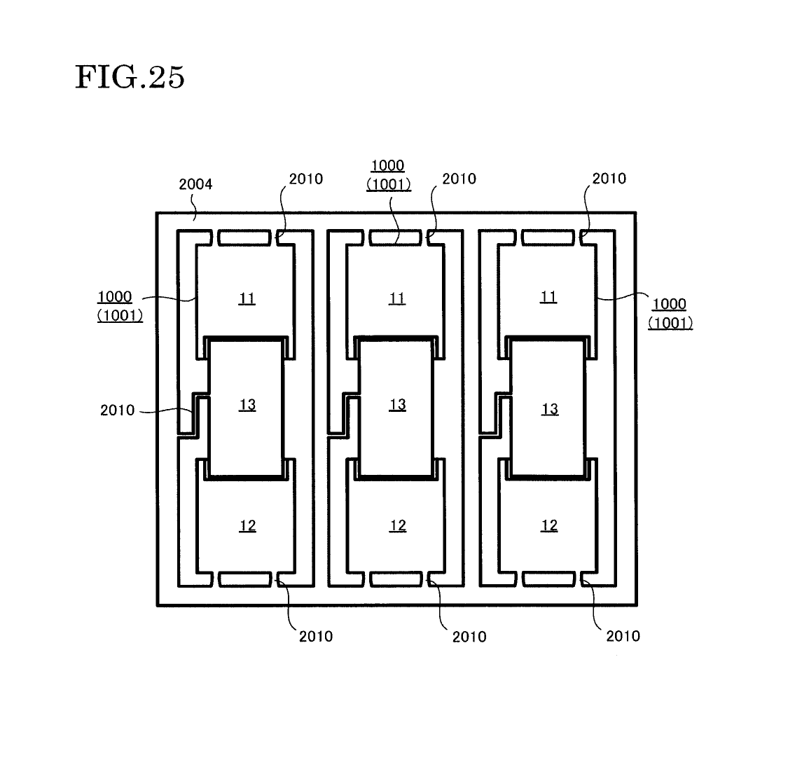

In flex-rigid wiring board 1000 or 1001 according to the above first or second embodiment, flexible wiring board 13 may be connected to frame 2004 by bridge 2010 as shown in FIG. 25, for example.

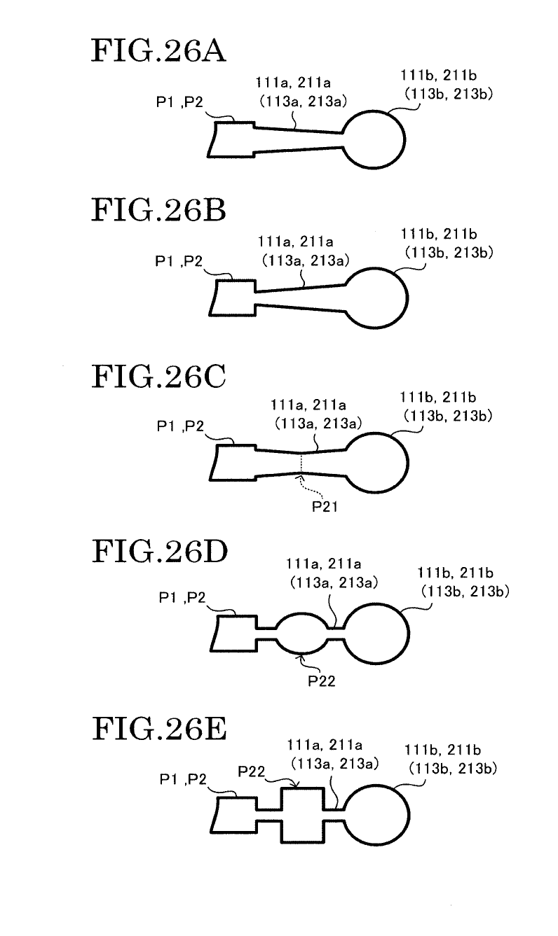

Conductive pattern (113a) (first conductive pattern) and conductive pattern (213a) (second conductive pattern) in flex-rigid wiring board 1000 of the above first embodiment as well as conductive pattern (111a) (first conductive pattern) and conductive pattern (211a) (second conductive pattern) in flex-rigid wiring board 1001 of the above second embodiment are each shaped straight (FIGS. 4A, 4B, 19A, 19B). However, that is not the only option, and the shape of each conductive pattern may be determined freely. For example, as shown in FIGS. 26A˜26C, the shape of each conductive pattern may be tapered. In the example in FIG. 26A, the width of a conductive pattern increases toward pad (P1) or (P2). In the example in FIG. 26B, the width of a conductive pattern decreases toward pad (P1) or (P2). In the example in FIG. 26C, the width of a conductive pattern decreases from both of its ends toward narrowed portion (P21) positioned in between. Alternatively, as shown in FIG. 26D or 26E, a conductive pattern may have a circular or rectangular enlarged-width portion (P22), for example.

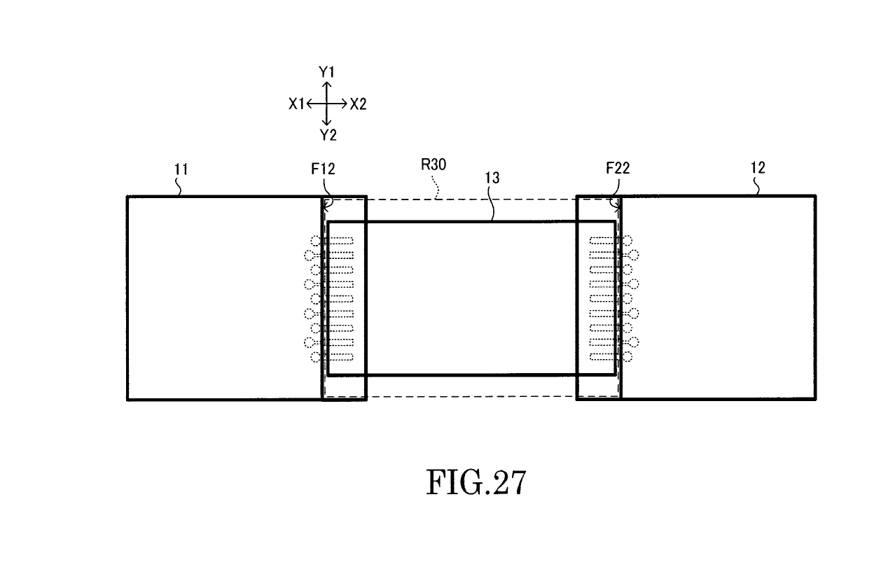

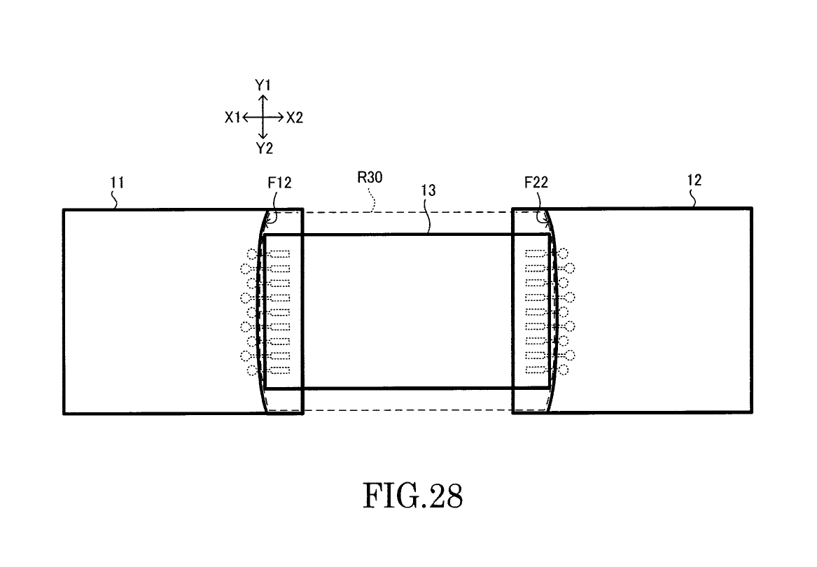

As shown in FIG. 27, it is an option if wall surfaces (F131, F132, F231, F232) are not formed and both sides of flexible wiring board 13 (lateral directions of flexible wiring board 13) are left open. In such a case as well, recessed portion (R30) is formed by setting opening portion (R10) to face opening portion (R20), allowing flexible wiring board 13 to be positioned in recessed portion (R30). In the example in FIG. 27, wall surfaces (F12, F22) are planar. However, that is not the only option, and wall surfaces (F12, F22) may be curved as shown in FIG. 28, for example.

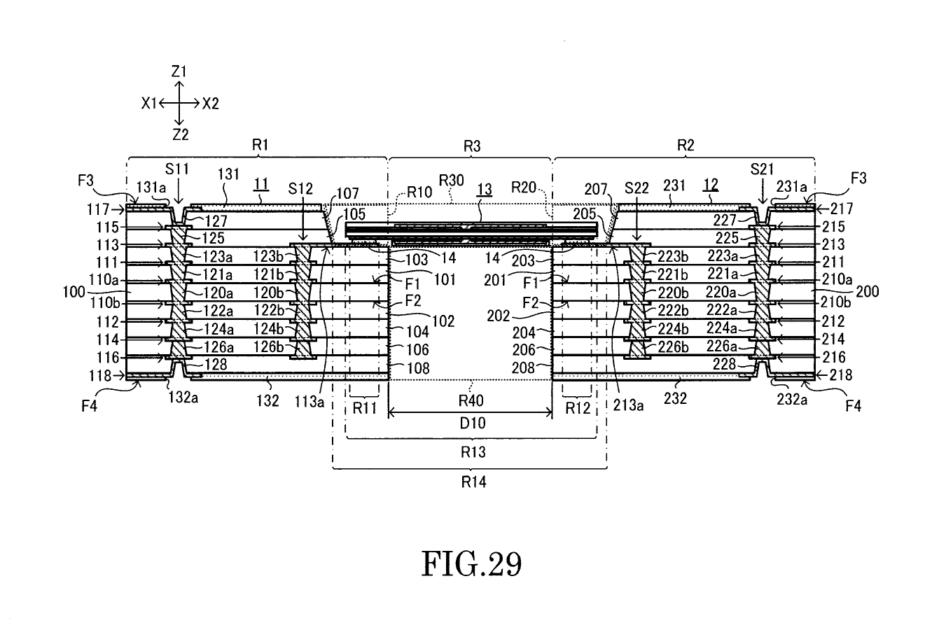

As shown in FIG. 29, opening portions (R10, R20) formed in rigid wiring boards (11, 12) (leading to recessed portion (R30) formed by those opening portions (R10, R20) may have tapered wall surfaces. In the example in FIG. 29, the opening area of recessed portion (R30) formed by opening portions (R10, R20) gradually increases toward the upper surface (on the third-surface (F3) side).

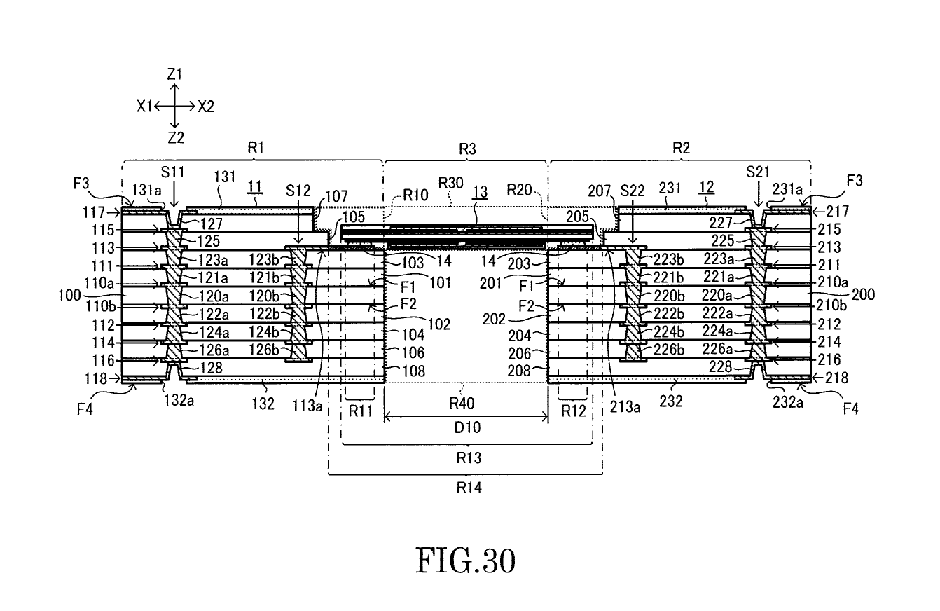

As shown in FIG. 30, three or more steps (three steps, for example) may be formed by each of opening portions (R10, R20) in rigid wiring boards (11, 12). In the example in FIG. 30, the opening area of recessed portion (R30) formed by opening portions (R10, R20) increases in steps toward the upper surface (on the third-surface (F3) side).

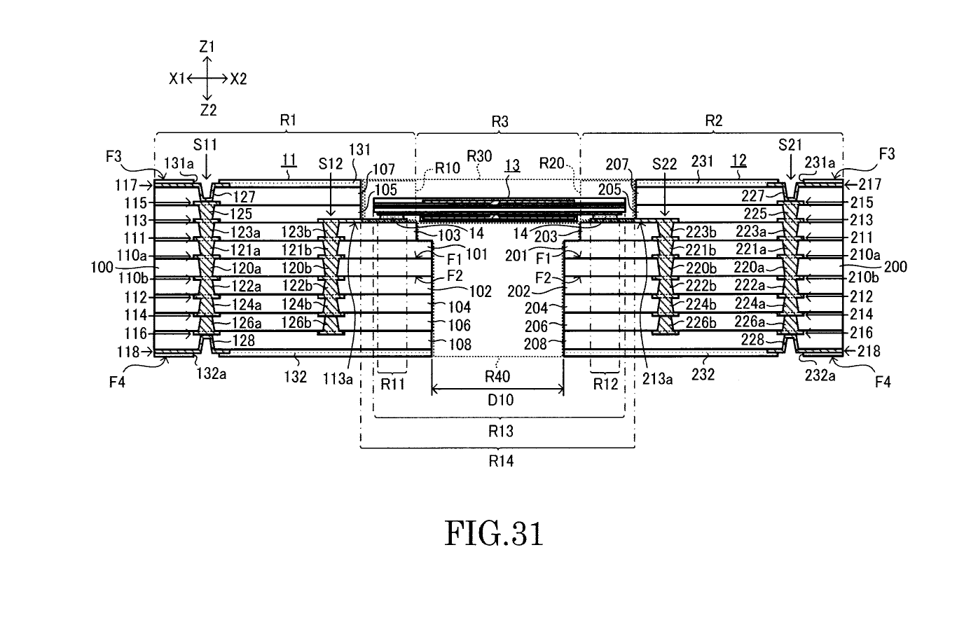

Alternatively, as shown in FIG. 31, flexible wiring board 13 may be positioned in the middle step of three or more steps (for example, steps with an upper step, middle step and lower step) formed by opening portions (R10, R20).

Opening portion (R10) of rigid wiring board 11 may have a different shape from that of opening portion (R20) of rigid wiring board 12.

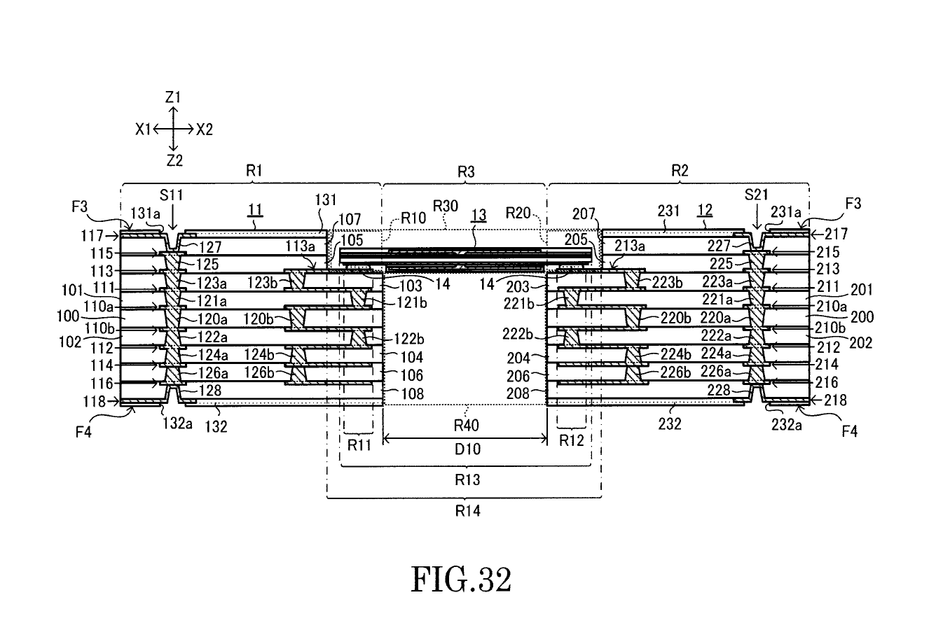

As shown in FIG. 32, a flex-rigid wiring board may be formed with rigid wiring boards (11, 12) which do not have a stacked-conductor structure.

Regarding other features, the structure of a rigid wiring board, a flexible wiring board or the like in a flex-rigid wiring board may be modified freely within a scope that does not deviate from the gist of the present invention.

A metal sheet may be built in a core substrate to improve strength or enhance heat dissipation.

A rigid wiring board or a flexible wiring board in a flex-rigid wiring board may be a single-sided wiring board which has conductive layers only on one side of a core substrate.

It is an option to surface mount an electronic component on a rigid wiring board or a flexible wiring board in a flex-rigid wiring board. Alternatively, an electronic component may be built into a rigid wiring board or flexible wiring board.

It is an option to connect three or more rigid wiring boards to a flexible wiring board.

The contents and order of the manufacturing method according to each of the above embodiments may be modified within a scope that does not deviate from the gist of the present invention. Also, some steps may be omitted depending on usage.

In each of the above embodiments, frame 2004 is separately prepared from rigid wiring boards (11, 12). However, rigid wiring board 11 or 12 (either first rigid wiring board or second rigid wiring board) may be formed to be integrated with a frame.

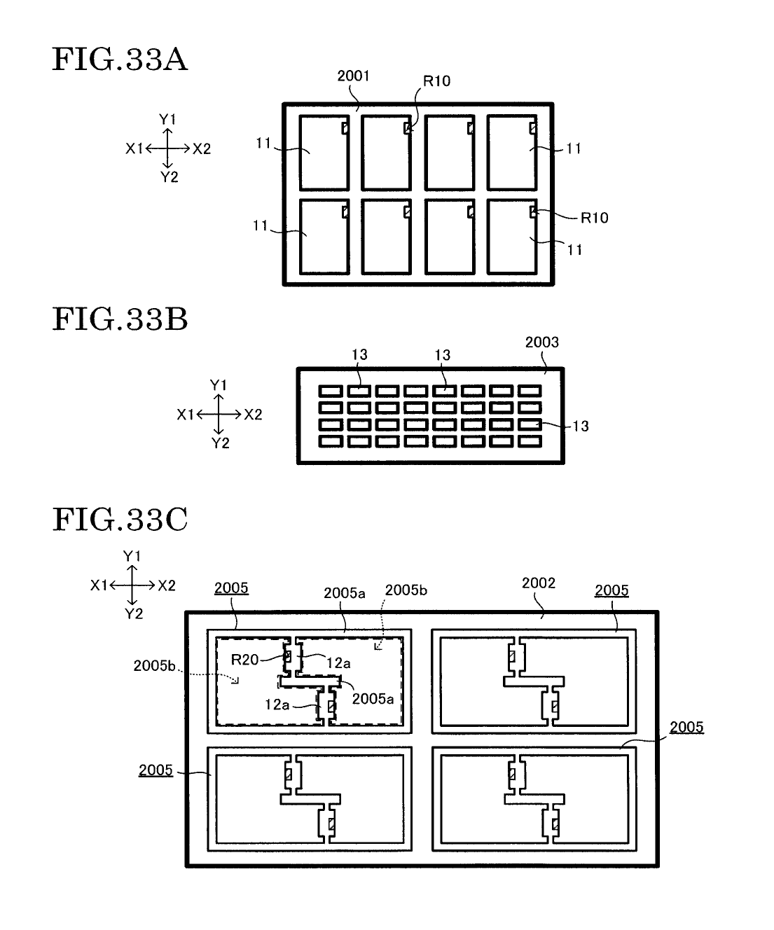

For example, as shown in FIG. 33A, multiple rigid wiring boards 11 (first rigid wiring boards) are collectively formed in panel 2001 in an integrated fashion. In addition, as shown in FIG. 33B, multiple flexible wiring boards 13 are collectively formed in panel 2001 in an integrated fashion. Then, as shown in FIG. 33C, multiple frame units 2005 are collectively formed in one panel 2002 in an integrated fashion.

Here, frame unit 2005 is structured with frame section (2005a) and multiple wiring board sections (12a) (rigid wiring boards 12) which are formed in an integrated fashion. Since frame section (2005a) and wiring board sections (12a) are collectively formed in a panel, they have the same layer structure as each other. Space (opening portion 2005b) to place rigid wiring board 11 is formed in a gap between frame section (2005a) and wiring board section (12a).

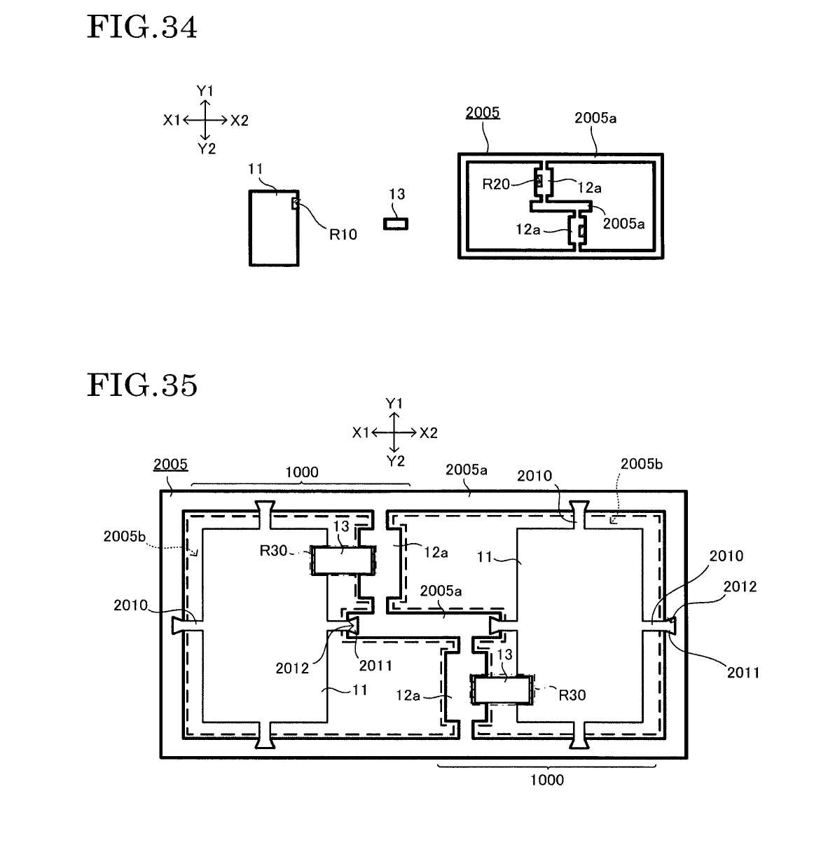

Next, using a router, for example, predetermined wiring boards are separated from each of panels (2001˜2003) so that each individual unit of rigid wiring board 11, flexible wiring board 13 and frame unit 2005 is obtained as shown in FIG. 34.

Next, as shown in FIG. 35, rigid wiring board 11 is placed in opening portion (2005b) of frame unit 2005, and connected to frame (2005a). Rigid wiring board 11 and frame (2005a) may be fixed to each other the same as in the first embodiment above.

Here, the number of conductive layers in wiring board section (12a) (rigid wiring board 12) is preferred to be lower than the number of conductive layers in rigid wiring board 11 (see FIG. 24, for example). By such a structure, sufficient frame strength is achieved in frame section (2005a) which has the same layer structure as that in wiring board section (12a).

Next, flexible wiring board 13 is placed in recessed portion (R30), and pad (P1) of rigid wiring board 11 and pad (P3) of flexible wiring board 13 as well as pad (P2) of rigid wiring board 12 and pad (P4) of flexible wiring board 13 are electrically connected respectively (see FIGS. 7A-7C). Accordingly, flex-rigid wiring board 1000 is connected to frame section (2005a) as shown in FIG. 35.

In examples shown in FIGS. 33A˜35, only rigid wiring board 11 or 12 (either a first rigid wiring board or a second rigid wiring board) is formed in an integrated fashion with a frame. However, that is not the only option. For example, the number of conductive layers in rigid wiring board 11 may be the same as the number of conductive layers in rigid wiring board 12, and rigid wiring boards (11, 12) (both of first and second rigid wiring boards) may each be formed in an integrated fashion with a frame.

The above embodiments and modified examples or the like may be combined. For example, a frame (see FIGS. 13A, 13B, 25, 35, etc.) may be applied to any flex-rigid wiring board shown in FIGS. 20˜24. Alternatively, any shape shown in FIGS. 26A˜26E may be applied to conductive patterns (111a, 211a) in the flex-rigid wiring board shown in FIG. 21, or conductive patterns (113a, 213a) in the flex-rigid wiring board shown in FIG. 22.

A flex-rigid wiring board according to an embodiment of the present invention has the following: a first rigid wiring board having a first opening portion that reaches a first inner insulation layer and a first connection terminal that is formed on the bottom surface of the first opening portion; a second rigid wiring board having a second opening portion that reaches a second inner insulation layer and a second connection terminal that is formed on the bottom surface of the second opening portion; and a flexible wiring board having a third connection terminal and a fourth connection terminal on a surface. In such a flex-rigid wiring board, the first rigid wiring board and the second rigid wiring board are positioned to be spaced apart in such a way that a recessed portion is formed by setting the first opening portion to face the second opening portion, the flexible wiring board is positioned in the recessed portion and the first connection terminal and the third connection terminal as well as the second connection terminal and the fourth connection terminal are electrically connected respectively, and a first conductor for interlayer connection is formed in the first insulation layer or its lower insulation layer in such a way to avoid being directly under the first connection terminal.

A method for manufacturing a flex-rigid wiring board according to another embodiment of the present invention includes the following: preparing a first rigid wiring board having a first opening portion that reaches a first inner insulation layer and a first connection terminal that is formed on the bottom surface of the first opening portion; preparing a second rigid wiring board having a second opening portion that reaches a second inner insulation layer and a second connection terminal that is formed on the bottom surface of the second opening portion; preparing a flexible wiring board having a third connection terminal and a fourth connection terminal on a surface; positioning the first rigid wiring board and the second rigid wiring board to be spaced apart; and positioning the flexible wiring board in a recessed portion formed by setting the first opening portion to face the second opening portion, and electrically connecting the first connection terminal and the third connection terminal as well as the second connection terminal and the fourth connection terminal. In such a method, a first conductor for interlayer connection is formed in the first insulation layer or its lower insulation layer in such a way to avoid being directly under the first connection terminal.

Obviously, numerous modifications and variations of the present invention are possible in light of the above teachings. It is therefore to be understood that within the scope of the appended claims, the invention may be practiced otherwise than as specifically described herein.

What is claimed is:

1. A flex-rigid wiring board, comprising:
a first rigid wiring board comprising a plurality of insulation layers including a first inner insulation layer, the first rigid wiring board having a first connection terminal formed on a surface of the first inner insulation layer;
a second rigid wiring board comprising a plurality of insulation layers including a second inner insulation layer, the second rigid wiring board having a second connection terminal formed on a surface of the second inner insulation layer; and
a flexible wiring board connecting the first rigid wiring board and the second rigid wiring board and having a third connection terminal formed on a surface of the flexible wiring board and a fourth connection terminal on the surface of the flexible wiring board,
wherein the first rigid wiring board and the second rigid wiring board have a first opening portion and a second opening portion, respectively, and are positioned such that the first rigid wiring board and the second rigid wiring board are spaced apart and form a recess portion comprising the first opening portion and the second opening portion facing each other, the flexible wiring board is positioned in the recessed portion such that the first connection terminal in the first rigid wiring board is connected to the third connection terminal in the flexible wiring board and that the second connection terminal in the second rigid wiring board is connected to the fourth connection terminal in the flexible wiring board, and the first rigid wiring board has a first interlayer connection conductor formed through one of the insulation layers in the first rigid wiring board such that the first interlayer connection conductor is not directly under the first connection terminal.

2. The flex-rigid wiring board according to claim 1, wherein the first interlayer connection conductor is formed through the first inner insulation layer, and the first connection terminal is electrically connected to the interlayer connection conductor through a first conductive pattern formed on the first inner insulation layer.

3. The flex-rigid wiring board according to claim 1, wherein the first interlayer connection conductor is formed in a lower insulation layer of the insulation layers positioned below the first insulation layer, and the first connection terminal is electrically connected to the first interlayer connection conductor through another interlayer connection conductor formed in the first insulation layer and a first conductive pattern formed on the lower insulation layer.

4. The flex-rigid wiring board according to claim 1, wherein the second rigid wiring board has a second interlayer connection conductor formed through one of the insulation layers in the second rigid wiring board such that the second interlayer connection conductor is not directly under the second connection terminal.

5. The flex-rigid wiring board according to claim 4, wherein the second interlayer connection conductor is formed through the second inner insulation layer, and the second connection terminal is electrically connected to the second interlayer connection conductor through a second conductive pattern formed on the second inner insulation layer.

6. The flex-rigid wiring board according to claim 4, wherein the second interlayer connection conductor is formed in a lower insulation layer of the insulation layers of the second rigid wiring board positioned below the second inner insulation layer, and the second connection terminal is electrically connected to the second interlayer connection conductor through another interlayer connection conductor formed through the second inner insulation layer and through a second conductive pattern formed on the lower insulation layer in the second rigid wiring board.

7. The flex-rigid wiring board according to claim 1, wherein the first interlayer connection conductor is formed such that the first interlayer connection conductor is positioned not directly under the flexible wiring board.

8. The flex-rigid wiring board according to claim 4, wherein the second interlayer connection conductor is formed such that the second interlayer connection conductor is positioned not directly under the flexible wiring board.

9. The flex-rigid wiring board according to claim 1, wherein the first interlayer connection conductor is not stacked on a lower interlayer connection conductor formed through a lower insulation layers below the first inner insulation layer and is electrically connected to the lower interlayer connection conductor through a conductive pattern formed on the lower insulation layer.

10. The flex-rigid wiring board according to claim 1, wherein the first rigid wiring board has a plurality of interlayer connection conductors including the first interlayer connection conductor and stacked in the first rigid wiring board, and each of the interlayer connection conductors comprises a filled conductor comprising a conductor material filling a hole through a respective one of the insulation layers in the first rigid wiring board.

11. The flex-rigid wiring board according to claim 4, wherein the second interlayer connection conductor is not stacked on a lower interlayer connection conductor formed through a lower insulation layers below the second inner insulation layer and is electrically connected to the lower interlayer connection conductor through a conductive pattern formed on the lower insulation layer.

12. The flex-rigid wiring board according to claim 4, wherein the second rigid wiring board has a plurality of interlayer connection conductors including the second interlayer connection conductor and stacked in the second rigid wiring board, and each of the interlayer connection conductors comprises a filled conductor comprising a conductor material filling a hole through a respective one of the insulation layers in the second rigid wiring board.

13. The flex-rigid wiring board according to claim 1, wherein the first rigid wiring board has a plurality of conductive layers which has a different number of layers from a plurality of conductive layers formed in the second rigid wiring board.

14. The flex-rigid wiring board according to claim 13, wherein one of the first rigid wiring board and the second rigid wiring board has a plurality of conductive layers which has a greater number of layers than a plurality of conductive layers formed in the other one of the first rigid wiring board and the second rigid wiring board, and the one of the first rigid wiring board and the second rigid wiring board has a plurality of interlayer connection conductors which are stacked in a substantially straight line in the one of the first rigid wiring board and the second rigid wiring board.

15. The flex-rigid wiring board according to claim 1, wherein the first connection terminal and the third connection terminal are electrically connected through a conductive resin, and the second connection terminal and the fourth connection terminal are electrically connected through a conductive resin.

16. The flex-rigid wiring board according to claim 15, wherein the conductive resin connecting the first connection terminal and the third connection terminal is an anisotropic conductive resin, and the conductive resin connecting the second connection terminal and the fourth connection terminal is an anisotropic conductive resin.

17. The flex-rigid wiring board according to claim 1, wherein the flexible wiring board has a portion where the third connection terminal is positioned in a thickness of the same as or less than a depth of the first opening portion, and the flexible wiring board has a portion where the fourth connection terminal is positioned in a thickness of the same as or less than a depth of the second opening portion.

18. The flex-rigid wiring board according to claim 1, wherein the first opening portion has a depth which is equal to a depth of the second opening portion.

19. The flex-rigid wiring board according to claim 1, wherein at least one of the first rigid wiring board and the second rigid wiring board is a unit separated from an assembly comprising a plurality of wiring boards formed in an integrated structure.

20. The flex-rigid wiring board according to claim 19, wherein each of the first rigid wiring board and the second rigid wiring board is a unit separated from an assembly comprising a plurality of wiring boards formed in an integrated structure.

21. A method for manufacturing a flex-rigid wiring board, comprising:
preparing a first rigid wiring board comprising a plurality of insulation layers including a first inner insulation layer, the first rigid wiring board having a first connection terminal formed on a surface of the first inner insulation layer;
preparing a second rigid wiring board comprising a plurality of insulation layers including a second inner insulation layer, the second rigid wiring board having a second connection terminal formed on a surface of the second inner insulation layer;
preparing a flexible wiring board having a third connection terminal formed on a surface of the flexible wiring board and a fourth connection terminal on the surface of the flexible wiring board;
positioning the first rigid wiring board and the second rigid wiring board spaced apart; and
connecting the flexible wiring board to the first rigid wiring board and the second rigid wiring board such that the first connection terminal in the first rigid wiring board is connected to the third connection terminal in the flexible wiring board and that the second connection terminal in the second rigid wiring board is connected to the fourth connection terminal in the flexible wiring board,
wherein the first rigid wiring board and the second rigid wiring board have a first opening portion and a second opening portion, respectively, and are positioned such that the first rigid wiring board and the second rigid wiring board form a recess portion comprising the first opening portion and the second opening portion facing each other, the flexible wiring board is positioned in the recessed portion, and the first rigid wiring board has a first interlayer connection conductor formed through one of the insulation layers in the first rigid wiring board such that the first interlayer connection conductor is not directly under the first connection terminal.

22. The method for manufacturing a flex-rigid wiring board according to claim 21, wherein the first interlayer connection conductor is formed through the first inner insulation layer, and the first connection terminal is electrically connected to the interlayer connection conductor through a first conductive pattern formed on the first inner insulation layer.

23. The method for manufacturing a flex-rigid wiring board according to claim 21, wherein the first interlayer connection conductor is formed in a lower insulation layer of the insulation layers positioned below the first insulation layer, and the first connection terminal is electrically connected to the first interlayer connection conductor through another interlayer connection conductor formed in the first insulation layer and a first conductive pattern formed on the lower insulation layer.

24. The method for manufacturing a flex-rigid wiring board according to claim 21, wherein the second rigid wiring board has a second interlayer connection conductor formed through one of the insulation layers in the second rigid wiring board such that the second interlayer connection conductor is not directly under the second connection terminal.

25. The method for manufacturing a flex-rigid wiring board according to claim 21, wherein at least one of the first rigid wiring board and the second rigid wiring board is prepared by separating a wiring board from an assembly comprising a plurality of wiring boards formed in an integral structure.

26. The method for manufacturing a flex-rigid wiring board according to claim 25, further comprising:
preparing a frame; and
connecting the first rigid wiring board and the second rigid wiring board to the frame.

27. The method for manufacturing a flex-rigid wiring board according to claim 25, further comprising:
integrating one of the first rigid wiring board and the second wiring board to a frame;
separating the other one of first rigid wiring board and the second wiring board from the assembly; and
connecting the other one of first rigid wiring board and the second wiring board to the frame.

28. The method for manufacturing a flex-rigid wiring board according to claim 27, wherein one of the first rigid wiring board and the second rigid wiring board has a plurality of conductive layers which has a greater number of layers than a plurality of conductive layers formed in the other one of the first rigid wiring board and the second rigid wiring board.
